(19) United States
(12) Patent Application Publication
(10) Pub. No.: US 2025/0076419 A1
(43) Pub. Date: Mar. 6, 2025

(54) DEVICE AND METHOD FOR DETECTING A MAGNETIC FIELD USING THE SPIN ORBIT TORQUE EFFECT

(71) Applicant: Infineon Technologies AG, Neubiberg (DE)

(72) Inventors: Dieter SUESS, Wien (AT); Udo AUSSERLECHNER, Villach (AT); Armin SATZ, Villach (AT)

(21) Appl. No.: 18/948,933

(22) Filed: Nov. 15, 2024

Related U.S. Application Data
(63) Continuation of application No. 17/220,129, filed on Apr. 1, 2021, now abandoned.

(30) Foreign Application Priority Data
Apr. 3, 2020 (DE) 102020204391.4

(51) Int. Cl. G01R 33/07; G01R 33/09; G11C 11/16; H01F 10/32; H10N 50/80

(52) U.S. Cl. CPC G01R 33/075; G01R 33/093; G01R 33/098; H01F 10/329; H10N 50/80; G11C 11/161

(57) ABSTRACT

A device includes at least one layer stack including a ferromagnetic layer, at least one magnetic reference layer, and a layer arranged therebetween having a magnetic tunnel junction. The at least one magnetic reference layer has a fixed first magnetization direction, and the ferromagnetic layer has a variable second magnetization direction that is variable relative to the first magnetization direction based on a spin orbit torque effect. The device further includes a spin orbit torque conductor arranged on a first side of the layer stack adjacent to the ferromagnetic layer, and a control unit configured to provide the spin orbit torque conductor with a time-variant input signal with temporally varying polarity and at the same time to determine a conductance of the tunnel junction dependent on the time-variant input signal and, based on the conductance, to detect a magnetic field acting on the device externally.

### RELATED APPLICATION

This application is a continuation of U.S. patent application Ser. No. 17/220,129, filed Apr. 1, 2021, which claims priority to Germany Patent Application No. 102020204391.4, filed on Apr. 3, 2020, the contents of which are incorporated herein by reference in their entireties.

### FIELD

Embodiments described herein relate to a device for determining an external magnetic field acting on the corresponding device and a corresponding method for determining the external magnetic field using the spin orbit torque effect.

### BACKGROUND

Many conventional magnetic sensors are based on materials that use the magnetoresistive effect, thus for example AMR sensors (AMR: Anisotropic Magnetoresistance), GMR sensors (GMR: Giant Magnetoresistance) or TMR sensors (TMR: Tunnel Magnetoresistance). However, these magnetic sensors are limited with regard to their ability to measure static magnetic field components with a high resolution. The offset error for this type of magnetic sensors depends inter alia on the individual device-to-device matching, which is in turn dominated by production limitations. The same applies to other magnetic sensors, too, such as Hall sensors, for example. However, a great advantage of Hall sensors is that all first-order mismatches can be eliminated by applying the so-called spinning current technique.

In order to implement signal conditioning methods, such as the spinning current technique, for example, in magnetoresistive sensors, it is desired to change the magnetization directions in defined magnetic layers. For AMR sensors, signal conditioning methods for reducing the magnetoresistive offset are known, for example, in which, by means of off-chip or on-chip coils, the AMR transfer curve is inverted by the magnetization direction being reversed. This is also referred to as the flipping AMR principle. However, one disadvantage here is the very high current consumption in order to be able to generate AMR flipping fields in the first place.

Therefore, it would be desirable to improve known magnetic sensors to the effect that their magnetization directions can be influenced in a simple and power-saving manner in order to detect magnetic fields, and in order for example to enable a precise compensation of disturbances, such as a highly precise offset compensation, for example.

### SUMMARY

To achieve this a device is proposed. The device includes at least one layer stack. The layer stack in turn includes at least one ferromagnetic layer and at least one magnetic reference layer. Arranged between the ferromagnetic layer and the magnetic reference layer is a further layer, which in turn has a magnetic tunnel junction. The at least one magnetic reference layer has a fixed first magnetization direction. Moreover, the ferromagnetic layer has a variable second magnetization direction. The second magnetization direction is variable relative to the first magnetization direction, specifically with use or application of the spin orbit torque effect (or SOT effect for short). The spin orbit torque effect, or SOT effect for short, is based on the spin orbit coupling of electrons. Examples of phenomena that can result in a spin orbit torque effect are the so-called spin hall effect or the Rashba-Edelstein effect, which can be observed at interfaces, in particular. The device furthermore includes a spin orbit torque conductor arranged on a first side of the layer stack, said first side being adjacent to the ferromagnetic layer. Moreover, the device includes a control unit configured to feed the spin orbit torque conductor with a time-variant input signal with temporally varying polarity and at the same time to determine a conductance of the at least one layer stack dependent on the time-variant input signal. The control unit is furthermore configured to detect, on the basis of the conductance determined, a magnetic field acting on the device externally.

The innovative concept described herein furthermore relates to a corresponding method for detecting an external magnetic field. This method involves providing at least one layer stack including a ferromagnetic layer and at least one magnetic reference layer and also including a layer arranged therebetween and having a magnetic tunnel junction. In this case, the at least one magnetic reference layer has a fixed first magnetization direction, and the ferromagnetic layer has a variable second magnetization direction, where the second magnetization direction is deflectable relative to the first magnetization direction on the basis of the spin orbit torque effect. Furthermore, the method involves providing a spin orbit torque conductor arranged on a side of the layer stack adjacent to the ferromagnetic layer. The method furthermore includes a step of feeding a time-variant input signal with temporally varying polarity into the spin orbit torque conductor. Furthermore, a conductance of the at least one layer stack dependent on the time-variant input signal is determined, and a magnetic field acting on the device externally is detected, on the basis of the conductance determined.

Embodiments and further advantageous aspects of the device and also of the method are mentioned in the respective dependent patent claims.

### BRIEF DESCRIPTION OF THE DRAWINGS

Some exemplary embodiments are illustrated by way of example in the drawing and are explained below. In the figures:

FIG. 1 shows a perspective view of a device in accordance with one exemplary embodiment,

FIG. 2A shows a schematic view of a layer arrangement for elucidating the SOT effect in the equilibrium state, i.e. when no external magnetic field acts on the layer arrangement,

FIG. 2B shows a schematic view of the layer arrangement from FIG. 2A for elucidating the SOT effect when an external magnetic field acts on the layer arrangement,

FIG. 3A shows diagrams for elucidating the excitation and the system response of the device,

FIG. 3B shows diagrams for elucidating the system response of the device in the case of external magnetic fields having various magnetic field strengths,

FIG. 4 shows an electrical equivalent circuit diagram of a device in accordance with one exemplary embodiment,

FIG. 5 shows a perspective view of a parallel-connected device in accordance with one exemplary embodiment,

FIG. 6 shows a perspective view of a series-connected device in accordance with one exemplary embodiment,

FIG. 7 shows an electrical equivalent circuit diagram of a device comprising two SOT conductors in accordance with one exemplary embodiment,

FIG. 8 shows an electrical equivalent circuit diagram of the device from FIG. 7 with two additional switches for reversing the polarity of the SOT current in the two SOT conductors,

FIG. 9 shows an excerpt from a diagram of a device with different feeding-in of the read-out current in accordance with one exemplary embodiment,

FIG. 10 shows a schematic view of a device in accordance with one exemplary embodiment comprising SOT conductors hardwired to one another,

FIG. 11 shows a device in accordance with one exemplary embodiment comprising an SOT element having two SOT conductors,

FIG. 12 shows an excerpt from a diagram of a device with a different arrangement of two layer stacks in accordance with one exemplary embodiment, and

FIG. 13 shows a block diagram of a method in accordance with one exemplary embodiment.

### DETAILED DESCRIPTION

Exemplary embodiments are descried in greater detail below with reference to the figures where elements having the same or a similar function are provided with the same reference signs.

Method steps which are illustrated in a block diagram and explained with reference to same can also be carried out in a different order than that depicted or described. Moreover, method steps which relate to a specific feature of a device are interchangeable with precisely this feature of the device, and this likewise applies the other way around.

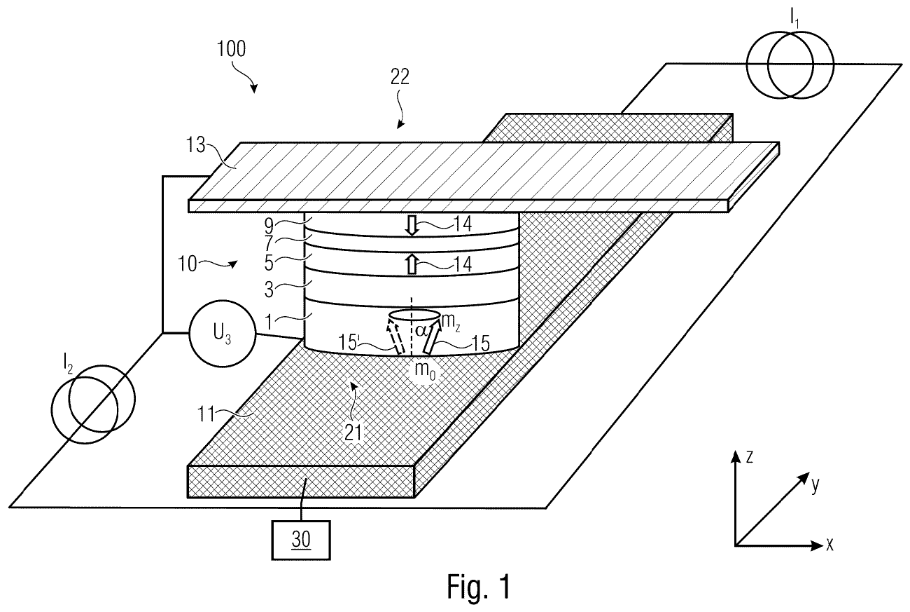

FIG. 1 shows a first exemplary embodiment of a device 100 in accordance with the innovative concept described herein.

The device 100 comprises at least one layer stack 10. The layer stack 10 comprises a ferromagnetic layer 1 and at least one magnetic reference layer. In the non-limiting example here, the layer stack 10 comprises three magnetic reference layers 5, 7, 9 arranged one above another. The layer stack 10 furthermore comprises a further layer 3, which can be arranged between the ferromagnetic layer 1 and the at least one magnetic reference layer 5, 7, 9. Said further layer 3 has a magnetic tunnel junction.

The at least one magnetic reference layer 5, 7, 9, which is also referred to as a pinned layer, has a fixed first magnetization direction 14. The magnetization direction can be understood to mean the preferred direction in which the majority of the elementary magnets situated in the magnetic reference layer 5, 7, 9 are aligned. This can be achieved by means of a corresponding magnetization of the reference layer 5, 7, 9, for example by the reference layer 5, 7, 9 being subjected to a strong external magnetic field or a strong current. In accordance with the concept described herein, the magnetization direction 14 of the reference layer 5, 7, 9 is fixed, that is to say substantially invariable.

In the non-limiting example depicted here, the fixed first magnetization direction 14 extends perpendicularly through the layer stack 10. In other words, the magnetization direction 14 extends substantially perpendicularly to the lateral extension direction of the respective layers 1, 3, 5, 7, 9 of the layer stack 10.

The ferromagnetic layer 1, by contrast, has a variable second magnetization direction 15. In this case, in particular, the magnetic moment, represented by the moment vector m_{z}, is variable, that is to say for example tiltable and/or rotatable, which will be explained in even greater detail later.

Since the ferromagnetic layer 1 has a variable magnetization direction 15, the ferromagnetic layer 1 is also referred to as a free layer or signal layer. In particular, the magnetization direction 15 of the ferromagnetic layer 1 is variable relative to the magnetization direction 14 of the at least one magnetic reference layer 5, 7, 9. By way of example, the magnetization direction 15 of the ferromagnetic layer 1, and in this case in particular the magnetic moment m_{z}, is tiltable or rotatable by a specific geometric angle α relative to the magnetization direction 14 of the at least one magnetic reference layer 5, 7, 9. This change in the magnetization direction 15, or the tilting and/or rotation of the magnetic moment m_{z}, of the ferromagnetic layer 1 can occur particularly when an external magnetic field acting on the device 100 is present.

The device 100 furthermore comprises a spin orbit torque (SOT) conductor 11. The spin orbit torque conductor 11 is arranged on a first side 21 of the layer stack 10, said first side being adjacent to the ferromagnetic layer 1. In the example depicted here, the spin orbit torque conductor 11 and the ferromagnetic layer 1 are in direct contact with one another. However, it would likewise be conceivable for one or more intermediate layers (not explicitly depicted here) to be present between the spin orbit torque conductor 11 and the ferromagnetic layer 1.

The device 100 furthermore comprises a control unit 30. The control unit 30 is configured to feed the spin orbit torque conductor 11 with a time-variant input signal I₁. This time-variant input signal I₁ can be temporally variable insofar as it can have a temporally varying polarity, for example. The temporally varying input signal I₁ can be an alternating current signal, for example. Since the temporally variable input signal I₁ is conducted through the SOT conductor 11, the input signal I₁ can also be referred to as SOT current in the case of an alternating current signal.

Preferably, the polarity of the time-variant input signal (SOT current) I₁ can be exactly reversed, that is to say that the polarity of the input signal I₁ can be reversed in such a way that the magnitude of said input signal is the same in both directions, or such that the difference magnitude between first (e.g. positive) polarity and second (e.g. negative) polarity is equal to zero. In other words, the time-variant input signal I₁ can thus be average-free with respect to time. Consequently, the offset would also be average-free with respect to time, or equal to zero. It should also be mentioned here that the input signal I₁ can be variable around a freely selectable zero position, specifically symmetrically variable, i.e. in equal proportions in both directions around said freely selectable zero position. By way of example, an SOT current I₁ can have a zero position at 0 amperes, and the SOT current I₁ can be variable around the zero position in each case by the same magnitude both in the positive and in the negative polarity direction, e.g. by +1 A in the positive direction and −1 A in the negative direction. However, instead of 0 A, another value of a current intensity is also conceivable as zero position.

The control unit 30 can be configured to determine a conductance (or a change in conductance) of the layer stack 10, and in particular a conductance (or a change in conductance) of the tunnel junction in the intermediate layer 3. In this case, the conductance (or the change in conductance with respect to time) is dependent on the time-variant input signal I₁. It goes without saying that, instead of the conductance, synonymously the reciprocal of the conductance, i.e. the resistance (or a change in resistance) of the at least one layer stack 10, and in particular the resistance (or a change in resistance) of the tunnel junction in the intermediate layer 3, can be determined as well.

In order to determine the conductance or the change in conductance of the tunnel junction in the intermediate layer 3, the device 100 can comprise an electrical conductor 13. The electrical conductor 13 can be arranged on a second side 22 of the layer stack 10 situated opposite the first side 21 of the layer stack 10. The control unit 30 can be configured to feed a read-out current I₂ into said electrical conductor 13. Said read-out current I₂ then flows via the electrical conductor 13 perpendicularly through the layer stack 10, i.e. from the second side 22 of the layer stack 10 to the opposite first side 21 of the layer stack 10. An opposite current flow direction of the read-out current I₂ would likewise be conceivable. The read-out current I₂ can then flow back via the SOT conductor 11. A voltage U₃ can be tapped off between the first and the second sides 21, 22 of the layer stack 10. The conductance or the resistance of the layer stack 10, and in particular the conductance or the resistance of the tunnel junction in the intermediate layer 3, can be determined on the basis of this tapped-off voltage U₃.

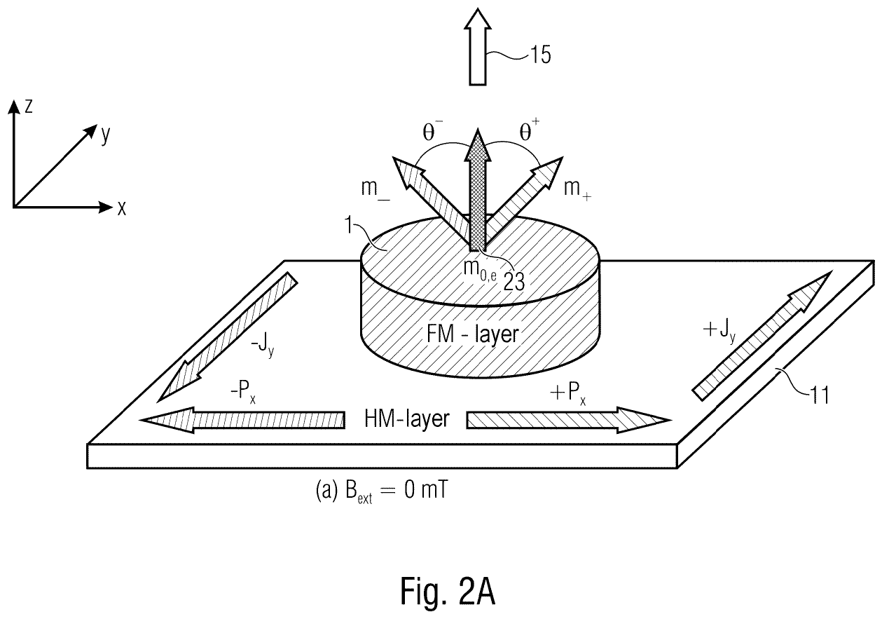

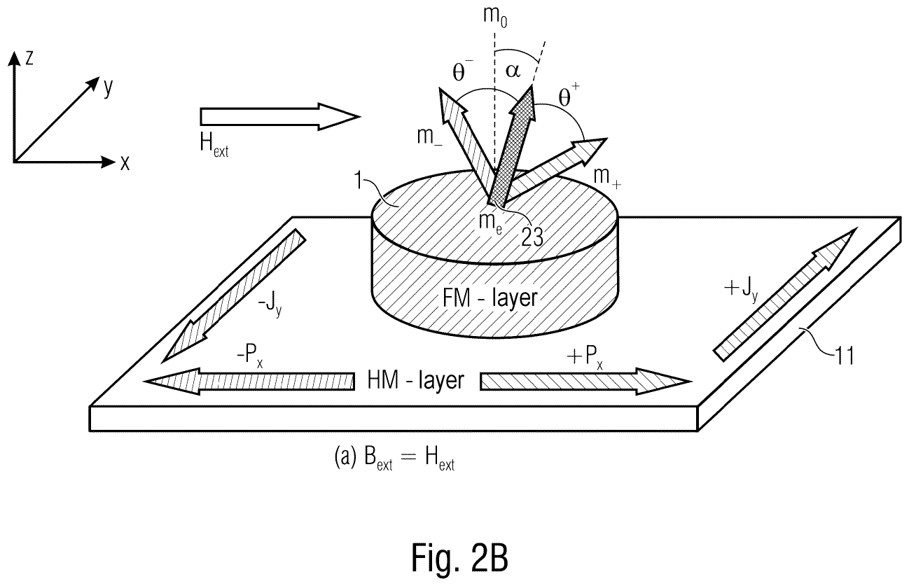

The conductance of the tunnel junction changes depending on the geometric angle a mentioned above, that is to say depending on how the variable second magnetization direction 15 of the ferromagnetic layer 1 is oriented relative to the fixed first magnetization direction 14 of the at least one magnetic reference layer 5, 7, 9. In this respect, reference should be made to FIGS. 2A and 2B at this juncture.

FIGS. 2A and 2B each show an SOT conductor 11 and a ferromagnetic layer 1 arranged thereon. In FIG. 2A, no external magnetic field is acting, whereas FIG. 2B illustrates a situation in which an external magnetic field Hₑₓₜ is acting on the device. The ferromagnetic layer 1 has a magnetic moment 23, which is also represented by the moment vector mₑ in the figures. The magnetic moment mₑ has a rest position m₀, in which the moment vector mₑ can be oriented parallel or antiparallel to the first magnetization direction 14 in the at least one magnetic reference layer 5, 7, 9 (not illustrated here). The moment vector mₑ can assume said rest position m₀ in particular in the equilibrium state, that is to say when no external magnetic field is acting on the device 100.

By means of applying a current ±I_{y} (I_{y} in FIGS. 2A and 2B corresponds to the input signal I₁ in FIG. 1) in the SOT conductor 11, the magnetic moment mₑ can be tilted or rotated. When a current +I_{y} in the positive y-direction is applied, a spin orbit torque +Pₓ in the positive x-direction acts on the magnetic moment mₑ, which is thereupon deflected from its rest position m₀ by a geometric angle Θ+ and tilts in the positive x-direction (see moment vector m+). When a current −I_{y} in the negative y-direction is applied, a spin orbit torque −Pₓ in the negative x-direction acts on the magnetic moment mₑ, which is thereupon deflected from its rest position m₀ by a geometric angle Θ− and tilts in the negative x-direction (see moment vector m−). The magnitude of the deflection of the moment vector mₑ from its rest position m₀ is dependent on the magnitude of the SOT current ±I_{y} in the SOT conductor 11.

The SOT current ±I_{y} here corresponds to the input signal I₁ mentioned above. Since the input signal is time-variant, the SOT current ±I_{y} can accordingly be an alternating current signal, i.e. the current flows alternately, resulting in the SOT currents ±I_{y} alternating in the positive and negative y-directions. This has the effect that the moment vector mₑ is likewise deflected in an alternating fashion around its rest position m₀ respectively in positive and negative directions (see moment vectors m+ or m−, respectively).

The SOT current ±I_{y} can be applied in an average-free manner, for example, i.e. the magnitude of the current intensity in the negative direction is equal to the magnitude of the current intensity in the positive direction. This has the effect that the moment vector mₑ is deflected around its rest position m₀ uniformly in the positive and negative directions. The moment vector mₑ rocks or oscillates back and forth as it were uniformly around its rest position m₀. This applies particularly in the equilibrium state, that is to say when no external magnetic field is acting on the device.

FIG. 2B shows the case in which an external magnetic field Hₑₓₜ is acting on the device. In this non-limiting example, the external magnetic field Hₑₓₜ is acting in the positive x-direction. Accordingly, the equilibrium state—described above with reference to FIG. 2A—of the moment vector mₑ changes, specifically in such a way that the moment vector mₑ is deflected out of its rest position m₀ in the positive x-direction in comparison with the equilibrium state (FIG. 2A). That is to say that the direction of the deflection of the moment vector mₑ depends on the direction of the externally acting magnetic field Hₑₓₜ.

Under the action of the external magnetic field, the moment vector me can deviate from its rest position m₀ in the equilibrium state (FIG. 2A) by an angle α. That is to say that upon the action of an external magnetic field Hₑₓₜ, the moment vector mₑ is tilted by a geometric angle α relative to its rest position m₀ in the equilibrium state. In this case, the magnitude of the deflection of the moment vector mₑ relative to its rest position m₀ in the equilibrium state (FIG. 2A) depends on the magnitude or the strength of the external magnetic field Hₑₓₜ and can thus represent an indicator of at least one magnetic field component (e.g. magnitude or strength) of the external magnetic field Hₑₓₜ. One measure thereof may be the abovementioned conductance of the layer stack 10, which changes depending on the deflection of the moment vector mₑ.

Following this theoretical treatment with reference to FIGS. 2A and 2B, reference should now be made to FIG. 1 again. In the ferromagnetic layer 1, the magnetization direction 15 is represented by the moment vector m_{z}. The moment vector m_{z} here corresponds to the moment vector mₑ discussed above. Depending on the magnitude and the direction of the applied SOT current I₁, the moment vector m_{z}, as described above, is correspondingly deflected, such that the moment vector m_{z} can oscillate around its rest position m₀.

In the equilibrium state, that is to say when no external magnetic field is acting on the device 100, the moment vector m-oscillates around its zero position m₀ uniformly and in an average-free manner. In this case, the magnetization direction 15 in the ferromagnetic layer 1 is directed substantially parallel or antiparallel to the magnetization direction 14 in the at least one magnetic reference layer 5, 7, 9. Accordingly, the conductance of the layer stack 10 is relatively high (e.g. maximal) here. The conductance has a first value in this case.

If an external magnetic field Hₑₓₜ is acting on the device 100, however, then the moment vector m_{z}, as described above with reference to FIGS. 2A and 2B, tilts in a specific direction, this direction generally being dependent on the direction of the external magnetic field Hₑₓₜ. This in turn has the effect that the moment vector m_{z} in the ferromagnetic layer 1 tilts by a geometric angle α, in comparison with its rest position m₀ in the equilibrium state (FIG. 2A). Accordingly, therefore, the moment vector m_{z}, and hence therefore also the magnetization direction 15 in the ferromagnetic layer 1, would then be correspondingly tilted relative to the magnetization direction 14 in the at least one magnetic reference layer 5, 7, 9. This in turn has the effect that the conductance in the layer stack 10 changes. By way of example, the conductance can decrease. That is to say that the conductance of the layer stack 10 in this example would have a second value different than the first value in the equilibrium state. This value can be lower, for example, than the first value in the equilibrium state.

The conductance of the tunnel junction in the layer stack 10 can again be determined by applying the read-out current I₂ described above or by tapping off the voltage U₃ dropped across the layer stack 10. This is because the conductance of the layer stack 10 changes with the tilting of the moment vector m_{z}, or with the angular deviation α between the first and second magnetization directions 14, 15. Accordingly, the voltage U₃ across the layer stack 10 then changes as well. By way of example, the voltage U₃ in the equilibrium state can be equal to zero. If an external magnetic field is acting on the device 100, the voltage U₃ can assume a value different than zero.

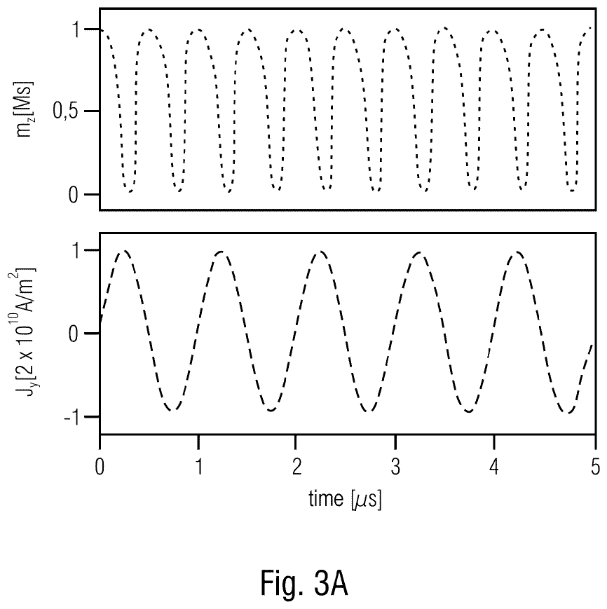

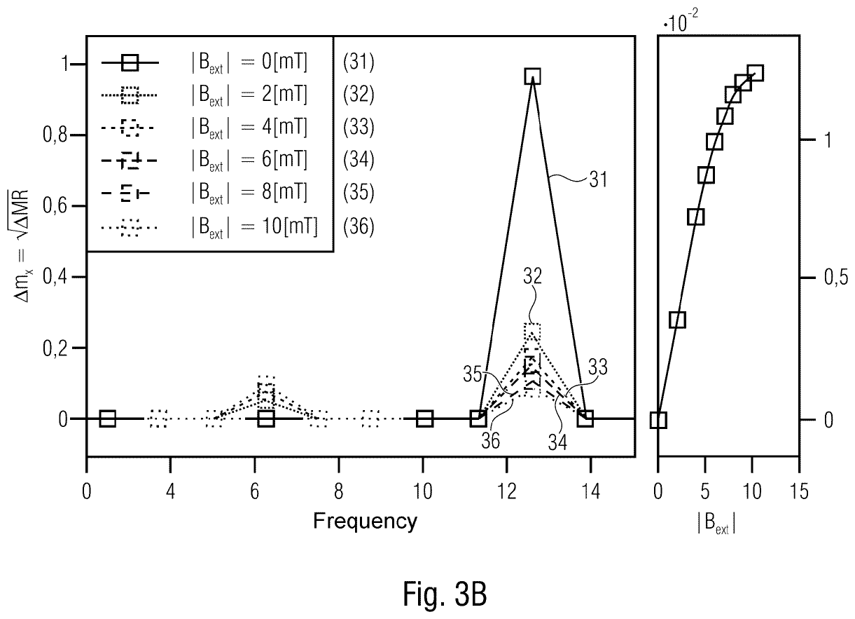

FIG. 3A shows a non-limiting example of a conceivable system response of the device 100 when an external magnetic field Hₑₓₜ acting on the device 100 is present. The lower function represents the input signal I₁ in the form of a sinusoidal alternating current signal. As a reminder, the time-variant input signal I₁ corresponds to the SOT current that flows through the SOT conductor 11.

The upper function reproduces the m_{z} response, that is to say the periodic excursion of the moment vector m_{z} in reaction to the current density of the applied time-variant SOT current I₁. In other words, a harmonic excitation (I₁=I₀sin(ωt)) by the SOT current I₁ (lower function) results in a second-order system response in the tunnel junction (upper function). As is discernible here, the curve of the m_{z} response deviates from a symmetrical periodic deflection. This indicates that the moment vector m_{z} is tilted by a geometric angle α relative to its rest position m₀ (FIG. 2A) in reaction to an external magnetic field Hₑₓₜ present. The m_{z} response is proportional to the voltage U₃ dropped across the layer stack 10 when the read-out current I₂ flows through the layer stack 10. That is to say that the m_{z} response is proportional to the read-out voltage U₃, which in turn again allows the conductance of the tunnel junction in the intermediate layer 3 to be deduced.

As is shown purely by way of example in FIG. 3B, the system response, that is to say the signal (U₃) tapped off at the tunnel junction or at the layer stack 10, can be subjected to a Fourier analysis in order to determine first- and second-order harmonic components. FIG. 3B depicts the Fourier transforms of the sensor responses for various external fields.

The frequency of the applied SOT current I₁ was ˜6 Hz. The left plot shows first and second harmonics at ˜6 Hz and at ˜12 Hz, respectively. The right plot shows the first harmonic relative to the external magnetic field Bₑₓₜ or Hₑₓₜ.

The first harmonic term is directly proportional to the external field component Bₑₓₜ. The first harmonic describes the natural frequency of the oscillation. For Bₑₓₜ=0 mT, the first harmonic is also equal to zero. This offset depends on the symmetry shown in FIG. 3B.

In accordance with the innovative concept described herein, therefore, the device 100 can be configured in such a way that a magnetic moment m_{z} is established in the ferromagnetic layer 1, on the basis of the spin orbit torque effect, and is deflectable symmetrically around a zero position m₀ in reaction to the time-variant input signal I₁ (FIG. 2A), and wherein the conductance of the tunnel junction changes depending on the deflection of the magnetic moment m_{z}. The control unit 30 in turn can be configured to determine the magnetic field Hₑₓₜ acting on the device 100 externally on the basis of a deviation of the magnetic moment m_{z} from the deflection thereof around the zero point m₀ (FIG. 2B).

For compensation of the disturbance variable caused by the external magnetic field Hₑₓₜ, which results in the tilting of the moment vector m_{z}, for example the SOT current I₁ in the SOT conductor 11 can be correspondingly adapted, for example increased. By means of a corresponding adaptation (e.g. increase or reduction) of the SOT current I₁, the tilting of the moment vector m_{z} can be compensated for or reversed again to an extent such that the moment vector m_{z} returns to its rest position m₀ again.

Therefore, if no external magnetic field is acting on the device 100, then the fixed first magnetization direction 14 and the variable second magnetization direction 15 can extend substantially parallel or antiparallel to one another. The conductance of the tunnel junction in the intermediate layer 3 can then assume a specific reference value, that is to say that the measured conductance (or resistance) of the tunnel junction can have a predetermined value and the voltage U₃ dropped across the layer stack 10 can likewise have a predetermined value, e.g. U₃=0 V. However, if an external magnetic field is acting on the device 100, then as a result there is a change in the position of the variable second magnetization direction 15 relative to the fixed first magnetization direction 14. As a result, there is also a change in the conductance in the tunnel junction of the intermediate layer 3, that is to say that the measured conductance (or resistance) deviates from the predetermined reference value mentioned above (without the action of the external magnetic field) and the voltage U₃ dropped across the layer stack 10 can assume a value different than zero.

The magnitude of this deviation can additionally represent a magnitude of the magnetic field strength of the external magnetic field detected. The control unit 30 can accordingly therefore be configured to detect a magnetic field acting on the device 100 externally, on the basis of the conductance determined.

As has already been mentioned briefly above, the second magnetization direction 15 in the ferromagnetic layer 1 can be varied by applying the input signal (SOT current) I₁ using the spin orbit torque effect.

The spin orbit torque effect, or SOT effect for short, is based on the spin orbit coupling of electrons. In principle, a device for using the SOT effect can comprise for example a double layer composed of a ferromagnetic material and a nonmagnetic material adjoining the latter. If a current in the in-plane direction is fed into the double layer, then a transverse spin current is generated at the boundaries of the double layer, the generation of said spin current being attributable to the spin orbit coupling of the electrons present there. This spin accumulation at the boundaries exerts a torque on the magnetization vector of the ferromagnetic layer and can change or switch the preferred direction of the magnetization in the ferromagnetic layer.

The spin orbit torque effect is used for example in memory components comprising a plurality of the double layers mentioned initially. For writing access to the memory component, the magnetization in the desired double layers can be switched using the spin orbit torque effect in order thus to set a desired bit sequence in the memory component, for example. In this case, an SOT current is applied in order to correspondingly set the magnetization directions. For a reading access, a read current different than the SOT current can be applied. The writing and reading, i.e. the application of the SOT current and the application of the read current, are effected separately from one another, depending on whether a write access or a read access is desired.

In accordance with one advantageous exemplary embodiment, the control unit 30 can be configured in such a way that the determination of the conductance or the change in conductance of the tunnel junction takes place at the same time as the application of the input signal I₁ to the SOT conductor 11. That is to say that the SOT current I₁ and the read-out current I₂ can be fed in simultaneously. This is a difference with respect to known memory components that use the SOT effect.

In the concept described herein, therefore, it has been recognized that the spin orbit torque effect can also be used in a suitable manner to realize a magnetic field sensor for determining an external magnetic field.

By way of example, the device 100 described herein can be used for switching and measuring magnetic fields. For this purpose, the device 100 can comprise a magnetic tunnel junction (MTJ for short) in combination with an SOT conductor 11. The insulation barrier of the tunnel junction can for example comprise magnesium oxide, or consist of magnesium oxide. The SOT conductor 11 can comprise or consist of a heavy metal, for example platinum.

On the one hand, the ferromagnetic layer 1 determines the signal response (U₃) of the magnetic tunnel junction. On the other hand, the magnetization direction 15 in the ferromagnetic layer I can be varied and controlled using the SOT effect, wherein the SOT effect is caused by an SOT current I₁ in the adjacent SOT conductor 11.

I₁ corresponds to a charging current which flows through the SOT conductor 11 (heavy metal layer) and can thus also be referred to as SOT current. The SOT current I₁ causes the SOT effect that can tilt the magnetic moment m_{z} in the ferromagnetic layer 1. The tilting can be effected toward the right and/or left, according to the polarity of the SOT current I₁.

I₂ corresponds to the read-out current which is conducted through the tunnel junction in order to determine the conductivity thereof. The conductivity of the tunnel junction changes in reaction to the geometric angle α between the moment vector m_{z} in the ferromagnetic layer 1 and the magnetization direction 14 of the magnetic reference layers 5, 7, 9. The intermediate layer 3 has the tunnel junction, that is to say an electrical insulation through which only a tunneling current can tunnel.

Accordingly, the device 100 can be referred to as a magnetoresistance (MR)-based magnetic measuring device. Moreover, corresponding methods are described herein for controlling magnetization states within the device 100 by means of electrical signals in order to generate sensor output signals that are as free of offset errors as possible. In accordance with the innovative concept described herein, the SOT effect is used to switch or rotate the MR magnetization. As a result, significantly larger signal ranges can be realized despite significantly lower current consumption in comparison with, for example, AMR flipping methods.

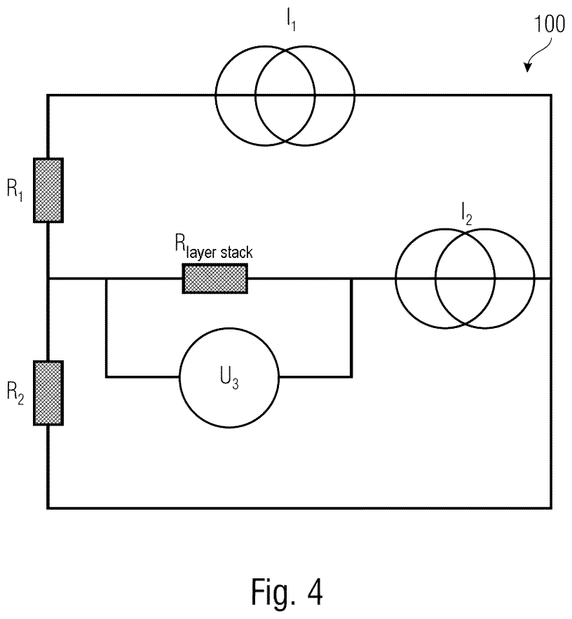

FIG. 4 shows an equivalent circuit diagram of a device 100 in accordance with the innovative concept described herein. The reference system of a tunnel junction in the magnetic reference layers 5, 7, 9 as depicted here is configured to measure out-of-plane magnetic field components. In other words, the tunnel junction (also referred to as tunnel barrier) responds to out-of-plane field components, which are also designated by B_{z} herein. The magnetization of the ferromagnetic layer 1 undergoes excursion symmetrically around its zero position m₀ as soon as an SOT current I₁ is applied in the SOT conductor 11.

In this regard, FIG. 2A shows that the equilibrium states of the moment vector mₑ are identical or symmetrical in the case of self-quenching or absent external magnetic fields, while the symmetry of the spin orbit torque mₑ is disturbed when an external magnetic field Hₑₓₜ is present (FIG. 2B).

Some non-limiting exemplary embodiments of various possibilities for connecting devices 100 will be discussed below.

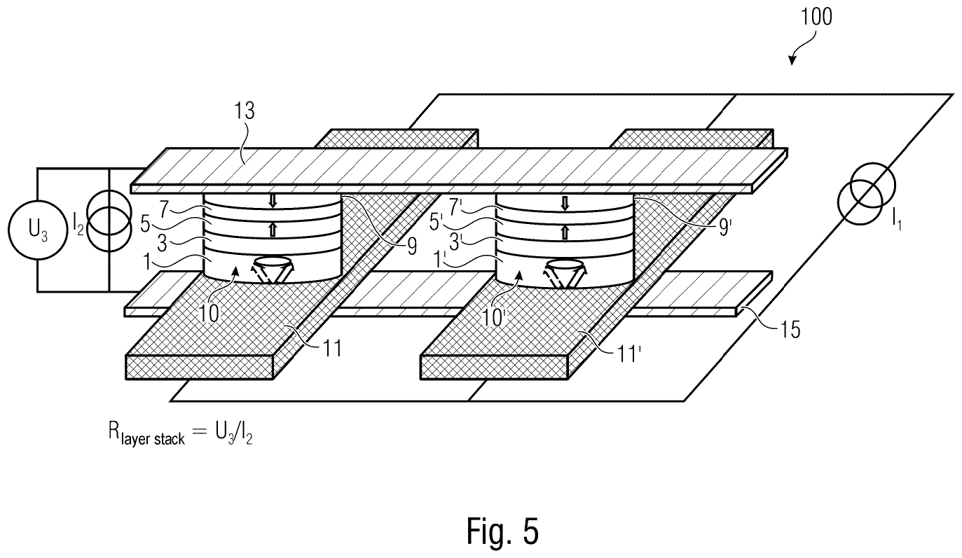

In this regard, for example, FIG. 5 shows a device 100 comprising a parallel connection of two layer stacks 10, 10′. In terms of their construction and function, both layer stacks 10, 10′ correspond to the layer stack 10 described above. In FIG. 5, the first layer stack 10 and the second layer stack 10′ are arranged respectively on an SOT conductor 11, 11′. The same SOT current I₁ can be fed into both SOT conductors 11, 11′.

The two SOT conductors 11, 11′ are connected to one another by means of a common electrical conductor 15. The electrical conductor 15 can be arranged on a side of the respective SOT conductor 11, 11′ facing away from the respective layer stacks 10, 10′. The electrical conductor 15 can be arranged in parallel, and opposite in a mirror-inverted fashion with respect to the electrical read-out conductor 13. The read-out current I₂ can be fed in between the two electrical conductors 13, 15. The voltage U₃ can be tapped off between the two electrical conductors 13, 15.

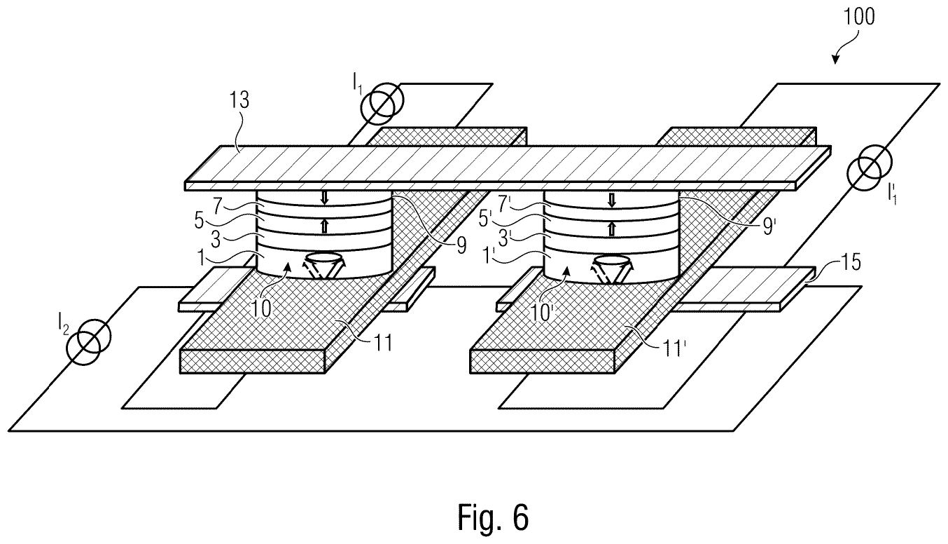

FIG. 6 shows a device 100 comprising a series connection of two layer stacks 10, 10′. In terms of their construction and function, both layer stacks 10, 10′ correspond to the layer stack 10 described above. In FIG. 6, the first layer stack 10 and the second layer stack 10′ are arranged respectively on an SOT conductor 11, 11′. A first SOT current I₁ can be fed into the first SOT conductor 11. A second SOT current I₁′ can be fed into the second SOT conductor 11′.

The first SOT conductor 11 can have a first electrical conductor 15 on a side facing away from the layer stack 10. The second SOT conductor 11′ can have a second electrical conductor 15′ which is separate from the first electrical conductor 15, on a side facing away from the layer stack 10′. The same read-out current I₂ can be fed into both electrical conductors 15, 15′.

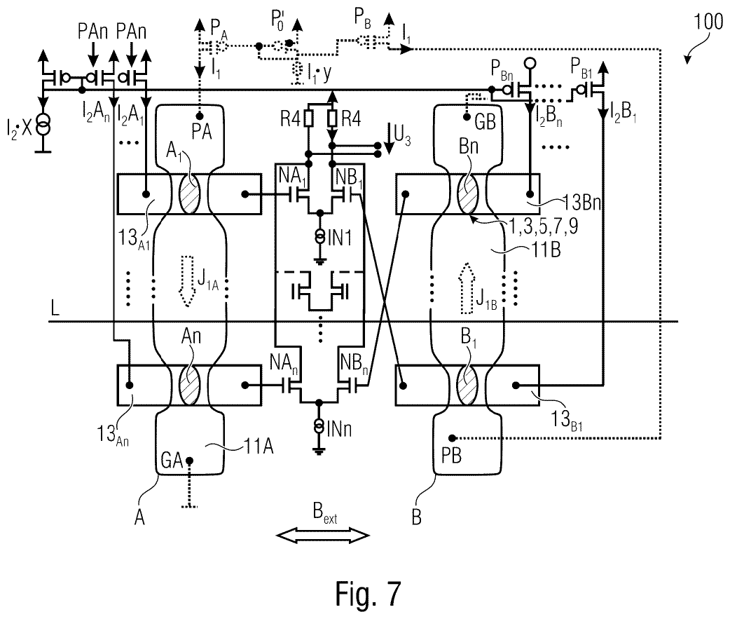

FIG. 7 shows a device 100 comprising two SOT conductors 11A, 11B arranged next to one another and extending in parallel fashion. For the sake of better distinguishability, the first SOT conductor arranged on the left in the Fig. is provided with the reference sign or indices A, and the SOT conductor arranged on the right in the Fig. is provided with the reference sign or indices B.

The first SOT conductor 11A has a first plurality of 1 to n layer stacks, and the second SOT conductor 11B has a second plurality of 1 to n layer stacks. For the sake of better distinguishability, the layer stacks of the first SOT conductor 11A are designated in terms of their cardinal number by A₁ to Aₙ. The layer stacks of the second SOT conductor 11B by contrast are designated in terms of their cardinal number by B₁ to Bₙ. In terms of their function and their construction, the layer stacks A₁ to Aₙ and B₁ to Bₙ depicted here correspond to the layer stack 10 discussed above.

In the circuitry depicted in FIG. 7, a first SOT current J_{1A} flows through the first SOT conductor 11A in a first direction, specifically from the feed-in point P_{A} (power) to G_{A} (ground). Along this first current flow direction J_{1A}, the first plurality (e.g. at least two) of 1 to n layer stacks A₁ to Aₙ are arranged one behind another in a series on the first SOT conductor 11A.

The second SOT conductor 11B is connected oppositely, i.e. the position of the feed-in point P_{B} (power) and the position of the coupling-out point G_{B} (ground) are arranged in a manner exactly mirror-inverted, i.e. rotated by 180°, in comparison with the first SOT conductor 11A. Consequently, a second SOT current J_{1B} flows through the second SOT conductor 11B in a second direction, opposite to the first direction mentioned above, specifically from the feed-in point P_{B} (power) to G_{B} (ground). Along this second current flow direction J_{1B}, the second plurality (e.g. at least two) of 1 to n layer stacks B₁ to Bₙ are arranged one behind another in series on the second SOT conductor 11B.

In other words, FIG. 7 shows a circuit and an arrangement for combining a plurality of 2n layer stacks A₁ to Aₙ and B₁ to Bₙ in a common sensor circuit. In this case, the sensor circuit can be divided into an SOT circuit (or bias circuit) and a read-out circuit. The SOT circuit supplies the SOT conductors 11A, 11B with a corresponding SOT current I₁. The read-out circuit supplies the circuit with read-out currents I₂A₁ to I₂Aₙ and I₂A₁ to I₂Aₙ.

FIG. 7 shows a plan view or a layout view of the two SOT conductors 11A, 11B with in each case a plurality (at least two) of layer stacks A₁ to Aₙ and respectively B₁ to Bₙ with magnetic tunnel junctions (MTJs). Elements having the same function and/or the same construction as in the exemplary embodiments described above are provided with the same reference signs, thus for example the elements 1, 3, 5, 7, 9, 11, 13. The elements additionally illustrated here (e.g. PMOS-FETs, NMOS-FETs, resistors and wirings) should be understood as a circuit diagram. That is to say that the position of the circuit elements can be altered, but the other elements, e.g. the SOT conductors 11A, 11B and their layer stacks A₁ to Aₙ and B₁ to Bₙ, should remain in their respective orientation with respect to one another. Accordingly, it is conceivable for the SOT conductors 11A, 11B and their layer stacks A₁ to Aₙ and B₁ to Bₙ to be displaced translationally, but not turned rotationally. This makes it possible to ensure that a magnetic field Bₑₓₜ acting on the device 10 externally acts identically on the layer stacks A₁ to Aₙ and B₁ to Bₙ of the SOT conductors 11A, 11B, while the respective SOT currents J_{1A}, J_{1B} flow in opposite directions in the SOT conductors 11A, 11B, beneath the respective layer stacks A₁ to Aₙ and B₁ to Bₙ. As a result, the conductance of the layer stacks of one SOT conductor (e.g. of the first SOT conductor 11A) is increased, while the conductance of the layer stacks in the respective other SOT conductor (e.g. in the second SOT conductor 11B) correspondingly decreases by the same magnitude.

The SOT circuit can simultaneously feed one and the same SOT current I₁ into both SOT conductors 11A, 11B, for example by means of PMOS current mirrors P0′, PA, PB. The SOT current I₁ flows in opposite directions through the respective SOT conductors 11A, 11B (identified by the arrows J_{1A} and J_{1B}). The current-carrying directions J_{1A} and J_{1B} indicate the direction of the SOT current I₁ flowing through the respective SOT conductor 11A, 11B. Since the SOT current I₁ is one example of a time-variant input signal, the current-carrying directions J_{1A} and J_{1B} are also referred to herein as signal-carrying directions.

FIG. 7 thus shows one exemplary embodiment of a device 100 in which the first spin orbit torque conductor 11A is arranged in parallel fashion next to the second spin orbit torque conductor 11B. As an alternative thereto, the first spin orbit torque conductor 11A can be arranged along in a series with the second spin orbit torque conductor 11B. Furthermore, the control unit 30 can be configured to apply the time-variant input signal I₁ with temporally varying polarity to both the first and the second spin orbit torque conductor 11A, 11B, wherein the time-variant input signal I₁ at the second spin orbit torque conductor 11B is fed in oppositely to the time-variant input signal I₁ at the first spin orbit torque conductor 11A, such that the signal-carrying directions J_{1A}, J_{1B} of the time-variant input signal I₁ in the respective spin orbit torque conductors 11A, 11B are respectively directed oppositely to one another.

The SOT conductors 11A, 11B can have different widths in order to avoid an undesired voltage drop and formation of heat in regions between two layer stacks and to increase the current density in the vicinity of a layer stack. The layer stacks can have an oval shape deviating from the round shape, in order to enlarge their effective area and to enable the best possible yield with regard to the SOT current density J_{1A}, J_{1B}. It is advantageous not to use excessively small layer stacks, since very small layer stacks have a very large process variation and also poor device-to-device matching, a rather low reliability and relatively high flicker noise. Layer stacks would be conceivable having a size of 1 μm² to 100 μm² with a tendency towards the upper value. Apart from that, FIG. 7 shows only the two outer layer stacks of each SOT conductor 11A, 11B (A₁ and Aₙ, and B₁ and Bₙ). The other layer stacks therebetween are indicated by dots.

Each layer stack A₁ to Aₙ and B₁ to Bₙ of the first and second SOT conductors 11A, 11B is connected to a respective electrical conductor 13_{A1} to 13_{An} and respectively 13_{B1} to 13_{Bn}. A respective read-out current I₂A₁ to I₂Aₙ and I₂B₁ to I₂Bₙ can be fed into each of these electrical conductors 13_{A1} to 13_{An} and respectively 13_{B1} to 13_{Bn}. This circuit for feeding in the read-out current I₂ is also referred to herein as a read-out circuit.

In the non-limiting, exemplary embodiment depicted here, the read-out circuit comprises n differential amplifiers, which in their simplest form are embodied as differential NMOS input pairs with their individual tail currents IN1, . . . INn. All the drains NA1, . . . . NAn of the NMOS transistors are connected to a common (negative) output terminal. All the drains NB1, . . . NBn of the NMOS transistors are connected to a common (positive) output terminal. The output voltage U₃ is tapped off between these two output terminals. The sum of the drain currents flows through matched loads, referenced by reference signs R4. These may be for example resistors or active current sources in the amplifier circuit design.

It is evident here that there is an electrical coupling between the SOT current I₁ and the read-out currents I₂A₁ to I₂Aₙ and respectively I₂B₁ to I₂B. The SOT current I₁ is significantly greater than the respective read-out currents I₂A₁ to I₂Aₙ and respectively I₂B₁ to I₂Bₙ (i.e. the amplitude of the SOT current I₁ is significantly greater, for example 100 times or 1000 times or even 10 000 times greater, in the milliamperes range, wherein the read-out currents I₂A₁ to I₂Aₙ and respectively I₂B₁ to I₂Bₙ can be in the region of approximately 10 μA). The read-out currents I₂A₁ to I₂Aₙ, I₂B₁ to I₂Bₙ can be generated by means of banks of current mirrors, for example, as is illustrated by way of example with the PMOS transistors PA1 to PAn and PB1 to PBn in FIG. 7. The individual read-out currents I₂A₁ to I₂Aₙ, I₂B₁ to I₂Bₙ can thus be fed into the individual associated layer stacks A₁ to Aₙ and B₁ to Bₙ. The read-out currents I₂A₁ to I₂Aₙ, I₂B₁ to I₂Bₙ flow through the respective layer stack A₁ to Aₙ, B₁ to Bₙ into the common SOT conductor 11A and respectively 11B. As a result, for example, beneath the two layer stacks Aₙ and Bₙ, which are both at ground potential, in addition to the SOT current I₁, in each case there also flows the sum of the n read-out currents I₂A₁ to I₂Aₙ in the layer stack Aₙ and respectively I₂B₁ to I₂Bₙ in the layer stack Bₙ.

That is to say that when the time-variant SOT current I₁ becomes inverted, then the total current flowing through the layer stacks A₁ and B₁ is average-free. By contrast, the total current flowing through the layer stacks Aₙ and Bₙ has an average value of n*I₂/2. Corresponding intermediate values occur at the layer stacks arranged in each case between the layer stacks A₁ to Aₙ and respectively B₁ to Bₙ. As a reminder: the SOT current I₁ is time-variant, i.e. it changes its polarity upon switchover, while in contrast the read-out currents I₂A₁ to I₂Aₙ and I₂B₁ to I₂Bₙ can be time-invariant. That is to say that the inversion force that acts on the respective moment vectors in the ferromagnetic layers of the respective layer stacks (owing to the time-variant SOT current I₁ or respectively the summation current I₁+I₂ at the respective layer stack) at the points in time at which the SOT current I₁ has an inverted polarity in comparison with the read-out current I₂A₁ to I₂Aₙ and I₂B₁ to I₂Bₙ respectively present is reduced a little. Accordingly, the inversion force at the points in time at which the time-variant SOT current I₁ and the read-out currents I₂A₁ to I₂Aₙ and I₂B₁ to I₂Bₙ respectively present have the same polarity is increased a little. This effect is negligible if the amplitude of the SOT current I₁ is significantly greater than the amplitude of the respective read-out current I₂A₁ to I₂Aₙ and I₂B₁ to I₂Bₙ.

For this reason, one exemplary embodiment provides for the time-variant input signal I₁ to be an alternating electric current that is greater than the read-out current I₂A₁ to I₂Aₙ and I₂B₁ to I₂Bₙ flowing vertically through a respective layer stack A₁ to Aₙ and B₁ to Bₙ, respectively, by a factor of 100 to 10 000.

It is additionally evident in FIG. 7 that a respective one of the layer stacks A₁ to Aₙ of the first SOT conductor 11A is connected, and in particular cross-coupled to a respective one of the layer stacks B₁ to Bₙ of the second SOT conductor 11B. In this regard, it is evident that for example the first layer stack A₁ of the first SOT conductor 11A arranged in the current-carrying direction J_{1A} is coupled to the first layer stack B₁ of the second SOT conductor 11B arranged in the current-carrying direction J_{1B}. The current-carrying directions J_{1A} and J_{1B} of the first and second SOT conductors 11A, 11B, preferably in all embodiments, are directed antiparallel to one another, i.e. they run in opposite directions. Moreover, FIG. 7 depicts by way of example that the last layer stack Aₙ of the first SOT conductor 11A arranged in the current-carrying direction J_{1A} is cross-coupled to the last layer stack Bₙ of the second SOT conductor 11B arranged in the current-carrying direction J_{B}.

It is evident here that the respective layer stacks A₁ to Aₙ and B₁ to Bₙ are arranged on the respective SOT conductor 11A, 11B in terms of their cardinal number along the respective current-carrying direction J_{1A}, J_{1B} in said SOT conductor.

In other words, therefore, the 1 to n layer stacks A₁ to Aₙ of the first spin orbit torque conductor 11A can be arranged in terms of their cardinal number from 1 to n in a first direction along the first spin orbit torque conductor 11A. By contrast, the 1 to n layer stacks B₁ to Bₙ of the oppositely polarized second spin orbit torque conductor 11B can be arranged on the second spin orbit torque conductor 11B in terms of their cardinal number from 1 to n in a second direction, opposite to the first direction, along said second spin orbit torque conductor. In this case, a respective one of the 1 to n layer stacks A₁ to Aₙ of the first spin orbit torque conductor 11A can be electrically cross-coupled respectively to a layer stack B₁ to Bₙ of the second spin orbit torque conductor 11B with in each case the same cardinal number (that is to say, as described above, e.g. A₁ to B₁, A₂ to B₂, . . . , Aₙ to Bₙ).

This cross-coupling concerns, in particular, the read-out circuit, i.e. the respective read-out currents I₂A₁ to I₂Aₙ and I₂B₁ to I₂Bₙ are fed into the layer stacks A₁ to Aₙ and B₁ to Bₙ that are respectively cross-coupled to one another.

As mentioned initially, the read-out circuit can comprise n differential amplifiers comprising transistors which are embodied for example as differential NMOS input pairs with individual tail currents IN1, . . . . INn. All the drains NA₁, . . . NAₙ of the NMOS transistors can be connected to a common (negative) output terminal. All the drains NB₁, . . . NBₙ of the NMOS transistors can be connected to a common (positive) output terminal. The abovementioned cross-coupling of individual layer stacks of the first and respectively the second SOT conductor 11A, 11B can be effected via these transistors, for example, i.e. a respective circuit comprising respectively two transistors can be arranged between the layer stacks of the first and second SOT conductors 11A, 11B that are respectively cross-coupled to one another, wherein the respective layer stack A₁ of the first SOT conductor 11A can be coupled to the drain NA₁ of a first transistor, and the respective layer stack B₁ of the second SOT conductor 11B can be coupled to the drain NB₁ of a second transistor NB₁. The two transistors form a differential amplifier.

This cross-coupling of the respective layer stacks of the first and second SOT conductors 11A, 11B has a decisive advantage. The first differential input stage NA₁, NB₁ of the differential amplifier, as described by way of example above, is connected to the cross-coupled layer stacks A₁ and B₁. The second differential input stage NA₂, NB₂ is connected to the cross-coupled layer stacks A₂ and B₂, and so on, up to the n-th differential input stage, which is connected to the cross-coupled layer stacks Aₙ and Bₙ.

Ideally, when an external magnetic field is not present, the voltage between the layer stack Aₙ and ground GA is identical to the voltage between the layer stack Bₙ and ground GB. This holds true primarily if all the read-out currents I₂A₁ to I₂Aₙ and I₂B₁ to I₂Bₙ are identical, which can best be realized by the first SOT conductor 11A and the layer stacks A₁ to Aₙ thereof being mirror symmetrical with respect to the second SOT conductor 11B and the layer stacks B₁ to Bₙ thereof. In FIG. 7 this mirror symmetry is indicated by means of the horizontal line ‘L’ running through the center of the two SOT conductors 11A, 11B.

It should be noted that the ground potential at the nodes GA and GB can be 1 V, for example, provided that the entire circuit is supplied e.g. with a supply voltage of 4 V. In this case, the potentials at the current feed-in points can vary between 3 V (in the case of positive pulses of the SOT currents) and 1 V (in the case of negative pulses of the SOT currents). Alternatively, the ground nodes of all the tail currents IN1, IN1, etc. can be at a common potential of 0 V. At least 1 V would then still remain for the gate-source voltages of the NMOS transistors NA₁ to NAₙ and respectively NB₁ to NBₙ plus the saturation currents of the tail current sources, in order to ensure proper operation.

The NMOS transistors described purely by way of example herein can also be replaced by PMOS transistors, and vice versa. The voltage U₃ illustrated in FIG. 7 can additionally be processed further, for example by means of multi-stage operational amplifiers. Moreover, a certain feedback between the inputs and outputs, i.e. between the gates of the transistors NA₁ to NAₙ (which are coupled to the layer stacks A₁ to Aₙ of the first SOT conductor 11A) and the gates of the transistors NB₁ to NBₙ (which are coupled to the layer stacks B₁ to Bₙ of the second SOT conductor 11B), can be used to increase the linearity, the stability and/or the accuracy of the circuit or of the device 100. It is likewise conceivable not to carry out the summation of all differential input pairs at the terminals of U₃. In this case, there would be n times U₃ⱼ (where j=1, 2, . . . , n) and each output voltage U₃ⱼ would be able to be processed individually by means of individual feedback at the respective inputs NAⱼ, NBⱼ thereof. Finally, these individually amplified output voltages U₃ⱼ could then be summed to form a total output voltage U₃.

In summary, it can thus be emphasized that the device 100 can comprise at least two SOT conductors 11A, 11B with in each case a plurality 1 to n of layer stacks A₁ to Aₙ and B₁ to Bₙ respectively arranged thereon. A respective layer stack A₁ to Aₙ of the first SOT conductor 11A can be cross-coupled to a respective layer stack B₁ to Bₙ of the second SOT conductor 11B. Cross-coupled layer stack pairs are at the same electrical potential. A respective differential read-out element (e.g. differential amplifier) comprising two transistors, for example, can be arranged between two layer stacks cross-coupled to one another, for example between A₁ and B₁. A transistor can be connected to the respective layer stack (e.g. A₁) of the first SOT conductor 11A, and a second transistor can be connected to the respective layer stack (e.g. B₁) of the second SOT conductor 11B. In this way, all the layer stacks A₁ to Aₙ of the first SOT conductor 11A can be cross-coupled in each case individually to all the layer stacks B₁ to Bₙ of the second SOT conductor 11B. At each cross-coupled layer stack pair (e.g. A₁ to B₁, Aₙ to Bₙ), or at each differential read-out element, the respective output signal thereof, e.g. the respective read-out voltage U_{3P1} to U_{3Pn} thereof, can be tapped off. The conductance of the respective layer stack pair can be derived on the basis of the respective read-out voltage U_{3P1} to U_{3Pn}. The individual read-out voltages U_{3P1} to U_{3Pn} can then be combined to form the total voltage U₃. The total conductance of all the layer stacks present on the two SOT conductors 11A, 11B can then be determined on the basis of the total voltage U₃. Since the layer stack pairs, as described above, are cross-coupled to one another, their respective output signals can be measured differentially and be combined to form a total output signal U₃. This differential measurement of output signals can be performed by the control unit.

In other words, therefore, one embodiment of the device 100 described herein provides that the control unit 30 can be configured to carry out, for the purpose of determining the external magnetic field Hₑₓₜ, a differential measurement of output signals of a plurality of layer stacks A₁ to Aₙ and respectively B₁ to Bₙ by applying a read-out current I₂A₁ . . . I₂Aₙ at least to one of the 1 to n layer stacks (e.g. A₁) of the first spin orbit torque conductor 11A, said read-out current generating a first output signal representing the conductance of this layer stack A₁, and by applying a read-out current I₂B₁ . . . I₂Bₙ at least to one of the 1 to n layer stacks (e.g. B₁) of the second spin orbit torque conductor 11B, said read-out current generating a second output signal representing the conductance of this layer stack B₁. In this case, the at least one layer stack A₁ of the first spin orbit torque conductor 11A can be electrically cross-coupled to the at least one layer stack B₁ of the second spin orbit torque conductor 11B. In this case, the control unit 30 can be configured in such a way that at least the first output signal of the layer stack A₁ of the first SOT conductor 11A and the second output signal of the layer stack B₁ of the second SOT conductor 11B are combined with one another in order by this means to obtain a total output signal U₃ representing the external magnetic field acting on the entire device 100.

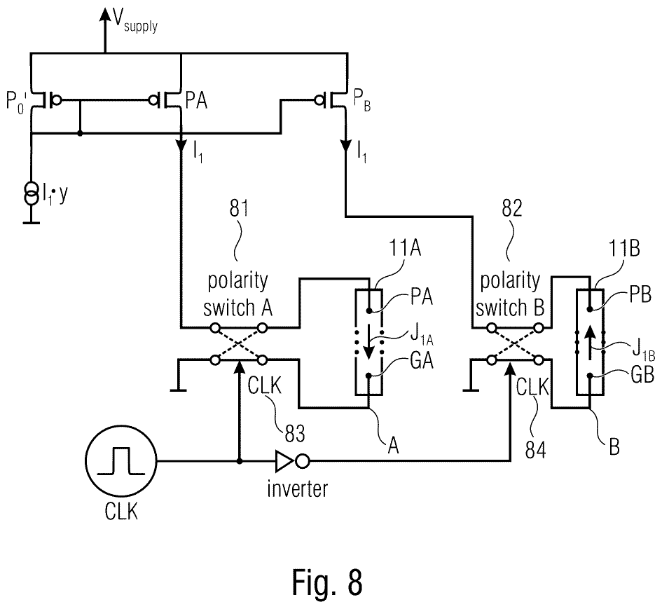

FIG. 8 shows a further variant of the exemplary embodiment from FIG. 7. FIG. 8, too, should be understood as a schematic circuit diagram. The embodiment in FIG. 8 differs from the embodiment from FIG. 7 essentially in that both SOT conductors 11A, 11B are additionally coupled to a switching device 81, 82. Otherwise, the embodiment from FIG. 8 corresponds to the embodiment discussed above with reference to FIG. 7, some details no longer being depicted here in comparison to FIG. 7, for the sake of better clarity.

In this regard, the first SOT conductor 11A is coupled to a first switching device 81, and the second SOT conductor 11B is coupled to a second switching device 82. The switching devices 81, 82 are configured to periodically switch the polarity of the SOT current I₁. This may be advantageous for example if a direct current source is used instead of an alternating current source.

The switching devices 81, 82 are a simple and cost-effective possibility for modulating the SOT current I₁ and by this means determining the value around which the magnetic moment vector m_{z} in the ferromagnetic layer 1 oscillates, in order to obtain a signal with the smallest possible zero error or offset error, which in turn corresponds to the error in the absence of the external magnetic field.

The two switching devices 81, 82 can be synchronized by means of a clock signal (CLK) 83 and an inverted clock signal (NOT CLK) 84. Antiparallel SOT currents are thus fed into the two SOT conductors 11A, 11B. These antiparallel currents move the magnetic moments in the two SOT conductors 11A, 11B in respectively opposite directions, when a homogeneous external magnetic field is present. This causes positive signal excursions for all the layer stacks A₁ to Aₙ on the first SOT conductor 11A and negative signal excursions for all the layer stacks B₁ to Bₙ on the second SOT conductor 11B. The layer stacks are thus well suited to be measured by means of differential amplifiers (see FIG. 7).

The device 100 depicted in FIG. 8 supplies a first output voltage U₃′ during a first operating phase, in which the switching devices 81, 82 are in a first state. The device 100 supplies a second output voltage U₃″ during a second operating phase, in which the switching devices 81, 82 are in a second state, in which the currents in the two SOT conductors 11A, 11B flow oppositely to the first operating phase. The device 100 then averages the two output voltages U₃′ and U₃″ in order to obtain a total output voltage U₃ that is corrected in respect of the offset error. The average value can be formed by means of a sample-and-hold circuit, for example. The sample-and-hold circuit can sample the voltages U₃′ and U₃″, for example, and an adding device can add the two sampled signals. Alternatively, the averaging can be realized by means of a low-pass filter. In this case, the output signals U₃′ and U₃″ can be low-pass-filtered with a cut-off frequency that is significantly lower than 1/T (where T is the duration of an operating phase).

The device 100 can additionally be optimized by further parameters. By way of example, the individual layer stacks A₁ to Aₙ and B₁ to Bₙ can be arranged next to one another or packed as close together as possible. All the layer stacks A₁ to Aₙ and B₁ to Bₙ would thus be subjected to the same temperature, the same mechanical stress and the same external magnetic field (and other conceivable disturbance variables such as process gradients resulting from production or electric field disturbance variables), which generally leads to the best measurement results.

In particular, it can be advantageous to arrange all the layer stacks A₁ to Aₙ and B₁ to Bₙ of the respective SOT conductor 11A, 11B in the current-carrying direction with the smallest possible spacing, in order to make the SOT chain of layer stacks A₁ to Aₙ and B₁ to Bₙ as short as possible. This in turn results in the lowest possible resistances in the SOT chain and thus in the lowest possible emission and also self-heating and temperature gradients. This additionally enables the shortest possible signal conductor lengths of the individual layer stacks A₁ to Aₙ and B₁ to Bₙ to the respective differential inputs of the amplifier circuits (NA₁−NB₁, NA₂−NB₂, . . . , NAₙ−NBₙ)—sec FIG. 7. In this case, it is advantageous for the lengths of the signal conductors of the two layer stacks connected to an amplifier to be configured to be of equal length as much as possible.

A further conceivable configuration of the read-out circuit is intended to be proposed with reference to FIGS. 7, 8 and 9. By way of example, odd-numbered layer stacks A₁, A₃, A₅, etc. can initially be identical to the layer stacks shown in FIG. 7. However, the read-out currents in the even-numbered layer stacks A₂, A₄, etc. could be supplied by means of NMOS current sources. That is to say that read-out currents are fed into the layer stacks having an odd cardinal number (A₁, A₃, A₅, . . . , and respectively B₁, B₃, B₅, . . . ) and read-out currents are extracted from the layer stacks having an even cardinal number (A₂, A₄, A₆, . . . , and respectively B₂, B₄, B₆, . . . ). This would, of course, likewise be conceivable the other way around.

This functions, however, only if the number n of layer stacks is odd, since the cross-coupling of layer stack pairs as discussed above presupposes that the read-out current is fed into e.g. B₁ whenever it is also fed into A₁. One advantage of this arrangement is that the total current (I₁+I₂) flowing through the SOT conductor 11A, 11B, along its current path from e.g. A₁ to Aₙ only between two adjacent layer stacks of the same SOT conductor, varies by in each case a value of one read-out current I₂. This results in significantly fewer deviations in the effective SOT current in all layer stacks A₁ to Aₙ and B₁ to Bₙ and thus in a significantly more uniform distribution of the quality of the magnetic field measurement by means of the device 100 or by means of all the layer stacks A₁ to Aₙ and B₁ to Bₙ. A further advantage consists in the significantly lower current consumption: instead of ˜2*n*I₂, the total current consumption is merely ˜n*I₂.

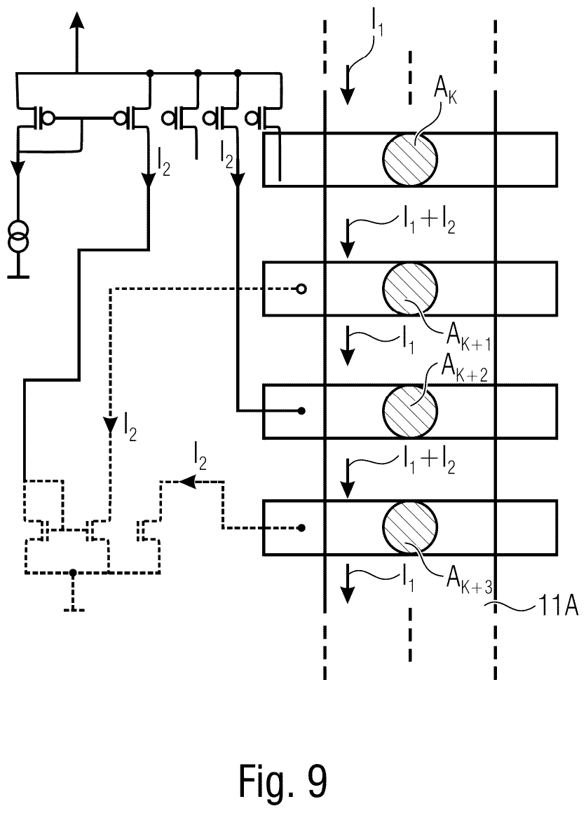

The principle just described will be explained again in greater detail with reference to FIG. 9. FIG. 9 shows an enlarged excerpt of an SOT conductor 11A with four layer stacks, which here are designated very generally by the notation Aₖ, Aₖ₊₁, Aₖ₊₂, Aₖ₊₃, etc.

As mentioned initially, in the case of the exemplary embodiment depicted in FIG. 7, all the read-out currents I₂A₁ to I₂Aₙ flow through the SOT conductor 11A. Consequently, the total current through the SOT conductor 11A below the n-th layer stack Aₙ is equal to I₁+n*I₂, while in contrast the total current below the first layer stack A₁ is only equal to I₁. That is to say that if the SOT conductor 11A has many layer stacks arranged in a series, then the total current along the SOT conductor 11A from the feed-in point PA at the first layer stack A₁ to the exit point GA at the n-th layer stack Aₙ will increase further and further. Therefore, the deflection of the moment vector m_{z} in the ferromagnetic layer of the n-th layer stack Aₙ is greater than the deflection of the moment vector m_{z} in the ferromagnetic layer of the first layer stack A₁.

This can be avoided with the exemplary embodiment depicted in FIG. 9 by virtue of the fact that the polarity alternates in every second layer stack. For example, a read-out current I₂ is fed into a first subset of layer stacks (e.g. all even-numbered layer stacks) Aₖ, Aₖ₊₂, Aₖ₊₄, etc. by means of PMOS transistors, and the read-out current I₂ is extracted from a second subset of layer stacks (e.g. all odd-numbered layer stacks) Aₖ₊₁, Aₖ₊₃, Aₖ₊₅, etc. by means of NMOS transistors. Consequently, the total current in the SOT conductor 11A varies only marginally between I₁ and I₁+I₂, such that this is negligible for accurate measurements.

In other words, one exemplary embodiment accordingly thus provides a device 100 in which the read-out current I₂ is fed in at a first subset Aₖ, Aₖ₊₂, Aₖ₊₄, etc. of layer stacks of the respective 1 to n layer stacks of the spin orbit torque conductor 11 or 11A, and wherein the read-out current is extracted at a second subset Aₖ₊₁, Aₖ₊₃, Aₖ₊₅, etc. of layer stacks of the respective 1 n layer stacks of the spin orbit torque conductor 11 or 11A.

The first subset can comprise for example even-numbered layer stacks, and the second subset can comprise for example odd-numbered layer stacks (in each case in the counting order of their arrangement on the SOT conductor in the current flow direction of the SOT conductor). This would also be conceivable the other way around. However, the subsets are not restricted to even and odd multiples. Other mathematical multiples may, of course, also be conceivable as subsets.

A further conceivable possibility for optimizing the device 100 could reside in swapping or alternating the current sources for the read-out current I₂, for example between even-numbered and odd-numbered layer stacks of an SOT conductor. This can be done continuously or intermittently. for example with high repetition rates of e.g. 10⁶ times per second, or alternatively with low repetition rates, such as e.g. once per second.

That is to say that it would be conceivable that, in a first operating phase, the read-out current I₂ is fed into the first layer stack A₁ and is extracted from the second layer stack A₂. In a second operating phase, the read-out current I₂ can then be fed into the second layer stack A₂ and be extracted from the first layer stack A₁. This increases the symmetry of the device 100 and improves the uniformity, the matching and the accuracy of all relevant layer stacks.

Expressed in somewhat more general words, one exemplary embodiment of a device 100 is thus conceivable in which in a first operating phase the read-out current I₂ is fed at a first subset (Aₖ, Aₖ₊₂, Aₖ₊₄, etc.) of layer stacks of the spin orbit torque conductor 11A and is coupled out at a second subset (Aₖ₊₁, Aₖ₊₃, Aₖ₊₅, etc.) of layer stacks of the spin orbit torque conductor 11A. In a second operating phase the read-out current I₂ can then be fed in at the second subset (Aₖ₊₁, Aₖ₊₃, Aₖ₊₅, etc.) of layer stacks of the spin orbit torque conductor 11A and can be coupled out at the first subset (Aₖ, Aₖ₊₂, Aₖ₊₄, etc.) of layer stacks of the spin orbit torque conductor 11A.

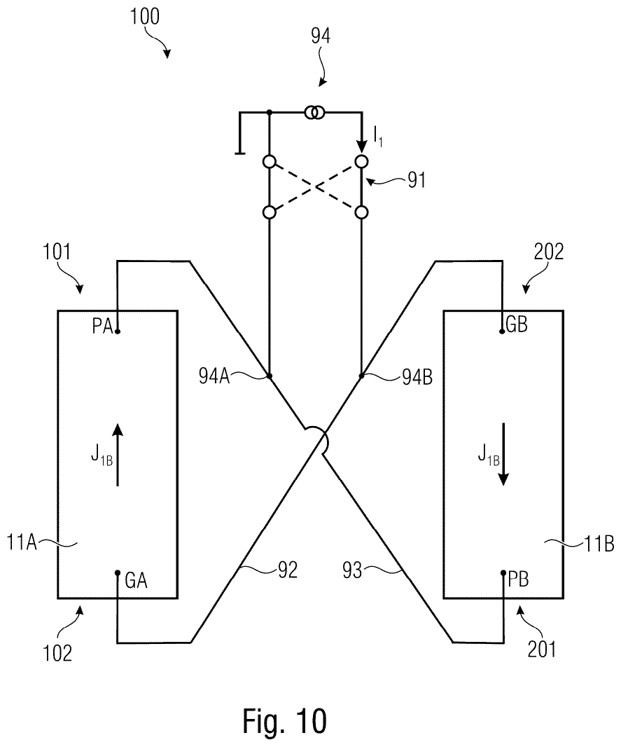

FIG. 10 shows a further conceivable exemplary embodiment of a device 100 which, in terms of construction, is substantially similar to the exemplary embodiments discussed above. One difference, however, resides in the type of electrical connection between the two SOT conductors 11A, 11B. Specifically, the two SOT conductors 11A, 11B here are hardwired to one another in the sense of a ring topology. That is to say that the first SOT conductor 11A can comprise a first section 101 having a first terminal PA (power) and also an opposite second section 102 having a second terminal GA (ground). The second SOT conductor 11B can likewise comprise a first section 201 having a first terminal PA (power) and also an opposite second section 202 having a second terminal GA (ground). The first section 101 of the first SOT conductor 11A and the first section 201 of the second SOT conductor 11B are hardwired to one another and are thus at the same electrical potential (e.g. power). The second section 102 of the first SOT conductor 11A and the second section 202 of the second SOT conductor 11B are hardwired to one another and are thus at the same electrical potential (e.g. ground). With regard to their terminals, the first SOT conductor 11A and the second SOT conductor 11B are arranged in a manner rotated by 180° with respect to one another. It is thus possible to realize the current flow direction J_{1A}, J_{1B} in opposite senses in the two SOT conductors 11A, 11B.

The wiring of the two SOT conductors 11A, 11B can be realized for example by means of metal wires or silicides in polysilicon. Generally, any material of low resistance is suitable for realizing the permanent hardwiring. The ring topology mentioned initially means, in the exemplary embodiment depicted in FIG. 10, going along the first SOT conductor 11A from the terminal GA to terminal PA, then along the wiring from PA to PB, then along the second SOT conductor 11B from PB to GB and finally along the wiring from GB to the starting point GA. The advantage of the hardwiring is that there are no MOS switches and thus no Rdson resistances of MOS switches along the path just described. Switches would cause a mismatch with regard to their Rdson resistances, which would in turn result in zero errors (offset errors) in the signal. This can be avoided by means of the hardwiring.

The hardwiring concerns the wiring of the SOT conductors 11A, 11b for the purpose of supply with the input signal, i.e. with the SOT current I₁. In order to generate a time-variant input signal I₁, the device 100 can comprise a switching device 91. A first pole of a current source 94 can be connected to a first wiring section 92, for example, wherein said first wiring section 92 connects the two first sections 101, 201 of the first and second SOT conductors 11A, 11B to one another. A second pole of the current source 94 can be connected to a second wiring section 93, for example, wherein said second wiring section 93 connects the two second sections 102, 202 of the first and second SOT conductors 11A, 11B to one another. The switching device 91 can be arranged between the two poles of the current source 94 in order to temporally vary the polarity of the SOT current I₁. This is advantageous in particular if a direct current source 94 is used. However, the current source 94 can also be an alternating current source.

It is advantageous not just if the current direction J_{1A}, J_{1B} in the two SOT conductors 11A, 11B is directed oppositely, rather if the fed-in SOT current I₁ in the two SOT conductors 11A, 11B is exactly halved, i.e. the resistances in both bridge branches should be identical to the greatest possible extent. This can be achieved by the feed-in and/or feed-out points 94A, 94B of the current source 94 lying exactly in the center.

In accordance with such an exemplary embodiment, therefore, the first spin orbit torque conductor 11A and the second spin orbit torque conductor 11B can be hardwired to one another in a ring-shaped topology, such that a first section 101 of the first spin orbit torque conductor 11A and also a first section 201 of the second spin orbit torque conductor 11B are at a first common potential (e.g. power), and such that a second section 102 of the first spin orbit torque conductor 11A and also a second section 202 of the second spin orbit torque conductor 11B are at a second common potential (e.g. ground). The device 100 can furthermore comprise at least one signal source 94 configured to feed the first spin orbit torque conductor 11A and the second spin orbit torque conductor 11B with a common input signal I₁. In this case, the signal source 94 can be configured to invert the common input signal I₁ in a time-variant manner, by means of the switching device 91 in the example. In this case, a first terminal 94A of the signal source 94 can be connected to the respective first hardwired sections 101, 201 of the two spin orbit torque conductors 11A, 11B, and a second terminal 94B of the signal source 94 can be connected to the respective second hardwired sections 102, 202 of the two spin orbit torque conductors 11A, 11B. As a result of this resulting cross-coupled hardwiring, the SOT current I₁ can be fed into the two SOT conductors 11A, 11B in opposite directions, such that the signal-carrying direction J_{1A} in the first spin orbit torque conductor 11A is opposite to the signal-carrying direction J_{1B} in the second spin orbit torque conductor 11B.

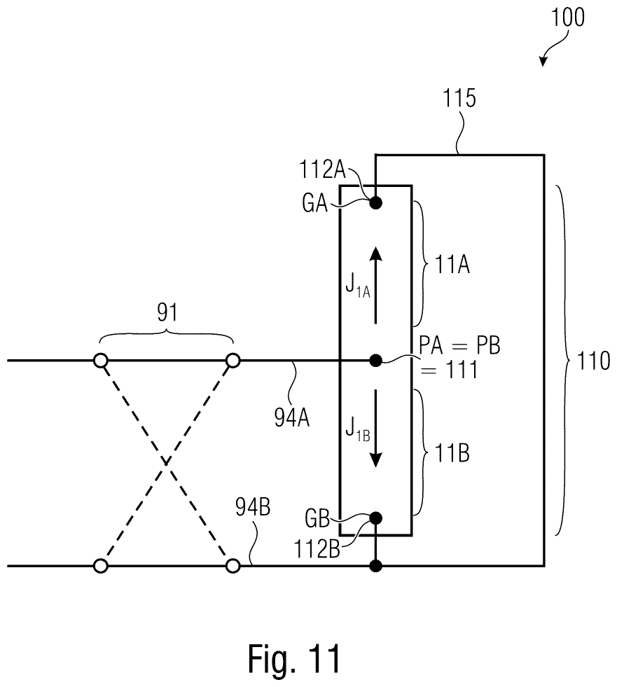

FIG. 11 shows a further exemplary embodiment of a device 100. Here, the first spin orbit torque conductor 11A and the second spin orbit torque conductor 11B are configured jointly in a single spin orbit torque element 110.

The spin orbit torque element 110 has a centrally arranged feed-in and/or feed-out point (also referred to as contact terminal) 111, which can be connected to a first pole 94A of a current source. A respective further feed-in and/or feed-out point (or contact terminal) 112A, 112B can be arranged at the two mutually opposite end sections of the elongated spin orbit torque element 110. The two feed-in and/or feed-out points 112A, 112B at the end sections of the spin orbit torque element 110 can be spaced at equal distances from the central feed-in and/or feed-out point 111. The two feed-in and/or feed-out points 112A, 112B can preferably be hardwired to one another by means of an electrical conductor 115 and also be connected to a second pole 94B of the current source. Moreover, a switching device 91 for inverting the polarity can be provided between the two poles 94A, 94B.

Consequently, the two contact terminals 112A, 112B can thus be at the same electrical potential. A first current flow direction J_{1A} can thus be established between the central feed-in and/or feed-out point 111 and the first contact terminal 112A in a first end section of the spin orbit torque element 110, and a second current flow direction J_{1B} can thus be established between the central feed-in and/or feed-out point 111 and the second contact terminal 112B in the opposite second end section of the spin orbit torque element 110. The two current flow directions J_{1A}, J_{1B} are directed oppositely.

Consequently, in the spin orbit torque element 110, the first SOT conductor 11A is formed as it were between the central feed-in and/or feed-out point 111 and the feed-in and/or feed-out point 112A in the first end section of the spin orbit torque element 110, and the second SOT conductor 11B is formed as it were between the central feed-in and/or feed-out point 111 and the feed-in and/or feed-out point 112B in the second end section of the spin orbit torque element 110. In this case, the central feed-in and/or feed-out point 111 forms a common contact terminal of the first and second SOT conductors 11A, 11B.

In other words, this common contact terminal 111 can subdivide the spin orbit torque element 110 into two SOT sections, i.e. into the first SOT conductor 11A and into the second SOT conductor 11B. The current flow directions J_{1A}, J_{1B} are directed oppositely in the two SOT sections or SOT conductors 11A, 11B.

The contact terminals and/or feed-in and feed-out points 111, 112A, 112B can be fashioned such that the SOT current I₁ is divided into two exactly equal portions (see J_{1A} and J_{1B}), i.e. the first SOT conductor 11A and the second SOT conductor 11B should have as far as possible identical sizes and dimensions. The feed-in/feed-out points 111, 112A, 112B should be positioned almost perfectly symmetrically, i.e. the central contact terminal 111 should be arranged as perfectly centrally as possible on the spin orbit torque element 110, and the first and second contact terminals 112A, 112B of the first and respectively the second SOT conductor 11A, 11B should be at distances from the central contact terminal 111 that are as equal as possible, and should be opposite one another as exactly at 180° as possible (proceeding from the central contact terminal 111). Very small asymmetries could result in offset/zero errors, i.e. an output signal U₃ not equal to zero would then arise even with a vanishing external magnetic field. A zero error as small as possible is desired, however, in the case of the device 100 described herein.

The contact terminals 112A, 112B at a distance from the central feed-in and/or feed-out point 111, and opposite one another, can be hardwired to one another by means of a low-resistance electrical conductor 115, for example by means of a metal wire. This avoids the need for a MOS switch between the two outer contact terminals 112A, 112B. As has already been mentioned further above, MOS switches have an Rdson mismatch. This would result in signal errors, and in particular in zero or offset errors (i.e. the output signal U₃ averaged over both polarities of the two SOT conductors 11A, 11B in FIG. 7 would then not be cancelled out in the absence of an external magnetic field). The central contact terminal 111 can also be hardwired by means of a low-resistance electrical conductor, and thus without MOS switches.

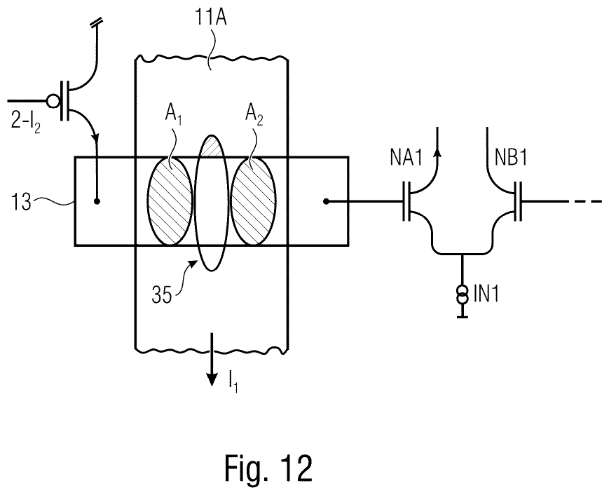

FIG. 12 shows a further exemplary embodiment for a possible arrangement of layer stacks A₁, A₂. FIG. 12 essentially shows an excerpt of the first SOT conductor 11A from FIG. 7. Here two layer stacks A₁, A₂ are arranged next to one another. That is to say that the two layer stacks A₁, A₂ are arranged next to one another perpendicularly to the current-carrying direction of the SOT current I₁ through the SOT conductor 11A. The read-out current I₂ can be fed into both layer stacks A₁, A₂ arranged next to one another by means of the electrical conductor 13. The read-out current I₂ can be multiplied by the number n of layer stacks A₁, A₂ arranged next to one another, i.e., in the case of the two layer stacks A₁, A₂ arranged next to one another as depicted here purely by way of example, the read-out current I₂ can be multiplied by the factor 2, such that 2*I₂ flows through the electrical conductor 13 to the layer stacks A₁, A₂.

In order to be able to accommodate a plurality (i.e. two or more) of layer stacks A₁, A₂ next to one another, the SOT conductor 11A can have a corresponding width. The current density J₁ in each layer stack A₁, A₂ can be increased by means of an optional hole 35 in the SOT conductor 11A. The hole 35 can be provided between the two layer stacks A₁, A₂. The electrical read-out conductor 13 can contact both layer stacks A₁, A₂, which are thus connected in series with one another. Consequently, a single current source is sufficient to feed the read-out current (here: 2*I₂) into the layer stacks A₁, A₂. A single differential input pair NA₁, NB₁ is likewise sufficient to tap the read-out current off again on the opposite side of the electrical conductor 13, i.e. after flowing through the layer stacks A₁, A₂. For better performance, the transfer conductance can likewise be multiplied by the number of layer stacks A₁, A₂, i.e. can be doubled in this example.

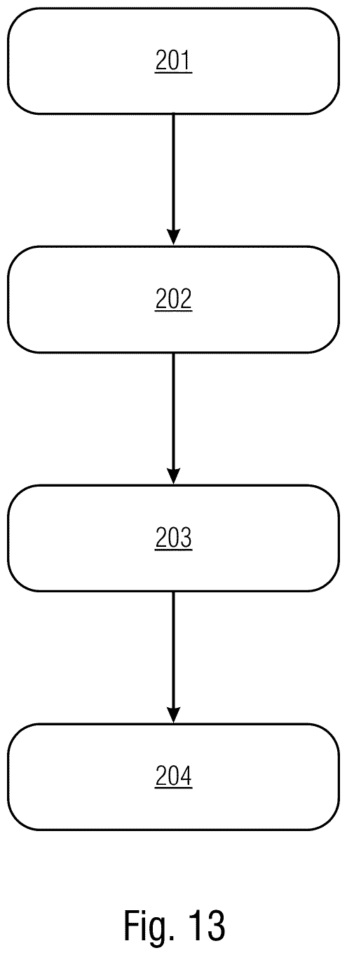

FIG. 13 shows a schematic block diagram of a method in accordance with the innovative concept described herein.

Block 201 involves providing at least one layer stack 10 comprising a ferromagnetic layer 1 and at least one magnetic reference layer 5, 7, 9 and a layer 3 arranged therebetween and having a magnetic tunnel junction. The at least one magnetic reference layer 5, 7, 9 can have a fixed first magnetization direction 14, and the ferromagnetic layer 1 can have a variable second magnetization direction 15, wherein the second magnetization direction 15 is variable relative to the first magnetization direction 14 on the basis of the spin orbit torque effect.

Block 202 involves providing a spin orbit torque conductor 11 or 11A arranged on a first side 21 of the layer stack 10, said first side being adjacent to the ferromagnetic layer 1.

Block 203 involves feeding a time-variant input signal I₁ with temporally varying polarity into the spin orbit torque conductor 11 or 11A.

Block 204 involves determining a conductance of the tunnel junction dependent on the time-variant input signal I₁. A magnetic field Hₑₓₜ acting on the device 100 externally is detected on the basis of the conductance determined.

The innovative concept described herein will be summarized once again briefly using different words below.

A purpose underlying the device 100 described herein resides, inter alia, in (i) supplying the SOT conductor(s) 11A, 11B with a corresponding SOT current I₁, (ii) providing the read-out current I₂ for all the layer stacks A₁ to Aₙ and respectively B₁ to Bₙ, and (iii) combining the individual output signals of the individual layer stacks to form a common output signal U₃ in order to reduce the statistical variation and the 1/f noise.

For this purpose, two or more SOT conductors 11A, 11B, connected to one another in accordance with the exemplary embodiments described herein, can be provided. The SOT conductors 11A, 11B can preferably be hardwired to one another without switches, specifically in the sense of a ring topology. Moreover, the device 100 can provide suitable signal sources configured to provide a defined SOT current I₁, which flows through the SOT conductors 11A, 11B in at least a first and a second operating phase, wherein the current flow direction J_{1A}, J_{1B} in the SOT conductors 11A, 11B is directed antiparallel or oppositely to one another in at least one operating phase.

The SOT conductors 11A, 11B can have layer stack pairs, wherein each layer stack pair comprises a layer stack A₁ of the first SOT conductor 11A and a layer stack B₁ of the second SOT conductor 11B. The layer stacks A₁, B₁ of such a layer stack pair can be arranged symmetrically with respect to one another in such a way that the electrical potential in both layer stacks A₁, B₁, in the absence of an external magnetic field Hₑₓₜ, is nominally identical. The output signals from one or more layer stack pairs A₁, B₁ of this type can be differentially read out and combined with one another to form a common output signal U₃ in order to obtain a robust average value with low flicker noise.

Some exemplary embodiments thus describe a magnetic sensor device 100 comprising a sensor element, in particular according to the GMR principle or the TMR principle. The magnetic sensor device 100 can furthermore comprise at least one layer 1 configured to generate a spin orbit torque (SOT) when a corresponding SOT current I₁ flows through. Said spin orbit torque influences the magnetic equilibrium state of the at least one layer 1, which then in turn results in a change in the resistance value of the GMR sensor element. The resistance value (alternatively the conductance) can be read out by means of applying a read-out current I₂. The SOT current I₁ and the read-out current I₂ can be applied simultaneously, i.e. at least at time intervals >0.1 ns.

The time-variant SOT current I₁ has an alternating polarity, such that an alternating current flow direction J_{1A}, J_{1B} is established in the respective SOT conductor 11A, 11B. This in turn has the effect that the magnetic moment vector m_{z} in the respective layer stack likewise oscillates alternately around its zero position m₀. That is to say that the magnetization direction 14 in the ferromagnetic layer 1 changes. In parallel with the excitation by means of the SOT current I₁, the magnetoresistive system response in the form of the conductance of the layer stacks of the respective SOT conductors 11A, 11B is measured and analyzed with regard to its different frequency contributions. The output of the device 100 is the analog signal of the system response, which signal can in turn be used as input for any type of Fourier analysis.

The device 100 described herein can additionally be realizable in the form of the following exemplary embodiments:

In accordance with one exemplary embodiment which is combinable with all exemplary embodiments described herein, a device 100 is proposed in which the first spin orbit torque conductor 11 or 11A has a constriction with reduced width in the region of at least one of the layer stacks A₁ to Aₙ arranged on said conductor, and/or in which the second spin orbit torque conductor 11B has a constriction with reduced width in the region of at least one of the layer stacks B₁ to Bₙ arranged on said conductor.

In accordance with one exemplary embodiment which is combinable with all exemplary embodiments described herein, a device 100 is proposed in which the first spin orbit torque conductor 11 or 11A and the second spin orbit torque conductor 11B each have the same number of layer stacks A₁ to Aₙ and B₁ to Bₙ, and/or in which the layer stacks A₁ to Aₙ provided on the first spin orbit torque conductor 11 or 11A are arranged mirror-symmetrically with respect to the layer stacks B₁ to Bₙ provided on the second spin orbit torque conductor 11B.

In accordance with one exemplary embodiment which is combinable with all exemplary embodiments described herein, a device 100 is proposed in which the time-variant input signal I₁ at the second spin orbit torque conductor 11B is fed in at the same time as the time-variant input signal I₁ directed oppositely thereto at the first spin orbit torque conductor 11A.

In accordance with one exemplary embodiment which is combinable with all exemplary embodiments described herein, a device 100 is proposed in which in each case two or more layer stacks A₁, A₂ are arranged next to one another on the spin orbit torque conductor 11A, wherein the two or more layer stacks A₁, A₂ are arranged transversely or perpendicularly to the direction of extent of the spin orbit torque conductor 11A or to the current flow direction of the SOT current I₁ in the SOT conductor 11A.

In accordance with one exemplary embodiment which is combinable with all exemplary embodiments described herein, a device 100 is proposed in which a hole 35 is provided in the spin orbit torque conductor 11A between the two layer stacks A₁, A₂ arranged next to one another.

In accordance with one exemplary embodiment which is combinable with all exemplary embodiments described herein, a device 100 is proposed in which the device 100 comprises a common feed network in order by this means to feed the first spin orbit torque conductor 11A and the second spin orbit torque conductor 11B with a common input signal I₁, and wherein the device 100 furthermore comprises a first and a second clocked switching device 81, 82, 83, 84, which are each configured to invert the common input signal I₁ in a time-variant manner, wherein the first clocked switching device 81, 83 is coupled to the common feed network and the first spin orbit torque conductor 11A, and wherein the second clocked switching device 82, 84 is coupled to the common feed network and the second spin orbit torque conductor 11B, and wherein the first and second switching devices 81, 82, 83, 84 are clocked in opposite senses, such that the current-carrying direction J_{1A} in the first spin orbit torque conductor 11A is antiparallel or opposite to the current-carrying direction J_{1B} in the second spin orbit torque conductor 11B.

Although some aspects have been described in association with a device, it goes without saying that these aspects also constitute a description of the corresponding method, such that a block or a component of a device should also be understood as a corresponding method step or as a feature of a method step. Analogously thereto, aspects which have been described in association with or as a method step also constitute a description of a corresponding block or detail or feature of a corresponding device.

The exemplary embodiments described above merely present an illustration of the principles of the innovative concept described herein. It goes without saying that modifications and variations of the arrangements and details described herein will be apparent to others skilled in the art. Therefore, the intention is for the concept described herein to be restricted only by the scope of protection of the appended patent claims, and not by the specific details which have been presented herein on the basis of the description and the explanation of the exemplary embodiments.

1. A device, comprising:
a layer stack comprising a ferromagnetic layer, at least one magnetic reference layer, and a layer arranged between the ferromagnetic layer and the at least one magnetic reference layer, wherein the layer has a magnetic tunnel junction,
wherein the at least one magnetic reference layer has a fixed first magnetization direction,
wherein the ferromagnetic layer has a variable second magnetization direction, and
wherein the variable second magnetization direction is variable relative to the fixed first magnetization direction based on a spin orbit torque effect;
a spin orbit torque conductor arranged on a first side of the layer stack, the first side being adjacent to the ferromagnetic layer;
an electrical conductor arranged on a second side of the layer stack situated opposite the first side of the layer stack; and
a control unit configured to feed the spin orbit torque conductor with a time-variant input signal and configured to feed in a read-out current between the electrical conductor and the spin orbit torque conductor, such that the read-out current passes through the layer stack in order to generate a voltage drop across the magnetic tunnel junction,
wherein the control unit is configured to feed the spin orbit torque conductor with the time-variant input signal at least in time intervals simultaneous with the read-out current between the electrical conductor and the spin orbit torque conductor, and
wherein the control unit is configured to detect a magnetic field acting on the device externally based on the time-variant input signal and the read-out current.

2. The device as claimed in claim 1, wherein a magnetic moment is established in the ferromagnetic layer, based on the spin orbit torque effect, and, in reaction to the time-variant input signal, oscillates symmetrically around a zero position of the magnetic moment,
wherein a deviation of the magnetic moment from the zero position of the magnetic moment results when the magnetic field acting on the device externally is present, and wherein a conductance of the magnetic tunnel junction changes depending on the deviation of the magnetic moment from the zero position, and
wherein the control unit is configured to detect the magnetic field acting on the device externally based on determining the conductance of the magnetic tunnel junction.

3. The device as claimed in claim 1, wherein the control unit is configured to feed the spin orbit torque conductor with the time-variant input signal at time intervals greater than 0.1 nanosecond (ns) simultaneous with the read-out current between the electrical conductor and the spin orbit torque conductor.

4. The device as claimed in claim 3, wherein the time-variant input signal is an alternating electric current that is greater than the read-out current flowing through the layer stack by a factor of 100 to 10 000.

5. The device as claimed in claim 1, further comprising:
a first plurality of 1 to n layer stacks, including the layer stack, wherein each layer stack of the first plurality of 1 to n layer stacks includes a first respective ferromagnetic layer, at least one first respective magnetic reference layer, and a first respective intermediate layer arranged between the first respective ferromagnetic layer and the at least one first respective magnetic reference layer, wherein the first respective intermediate layer has a first respective magnetic tunnel junction, wherein individual layer stacks of the first plurality of 1 to n layer stacks are arranged one behind another in a series along a current flow direction in the spin orbit torque conductor;
a second spin orbit torque conductor; and
a second plurality of 1 to n layer stacks, wherein each layer stack of the second plurality of 1 to n layer stacks includes a second respective ferromagnetic layer, at least one second respective magnetic reference layer, and second respective intermediate layer arranged between the second respective ferromagnetic layer and the at least one second respective magnetic reference layer, wherein the second respective intermediate layer has a second respective magnetic tunnel junction, and wherein individual layer stacks of the second plurality of 1 to n layer stacks are arranged one behind another in a series along a current flow direction in the second spin orbit torque conductor,
wherein n is an integer greater than 1.

6. The device as claimed in claim 5, wherein the spin orbit torque conductor and the second spin orbit torque conductor are configured jointly in a single spin orbit torque element,
wherein two mutually opposite contact terminals, including a first contact terminal and an opposite second contact terminal, of the single spin orbit torque element are each connected to a common first potential,
wherein the single spin orbit torque element has a central contact terminal which is arranged centrally between the first contact terminal and the opposite second contact terminal, and which is at a second potential, and
wherein the spin orbit torque conductor is formed in the single spin orbit torque element between the central contact terminal and the first contact terminal, and such that the second spin orbit torque conductor is formed between the central contact terminal and the opposite second contact terminal.

7. The device as claimed in claim 6, wherein the first contact terminal and the opposite second contact terminal of the single spin orbit torque element are hardwired to one another by means of an electrical conductor.

8. The device as claimed in claim 6, further comprising:
a switching device coupled between the central contact terminal and the two mutually opposite contact terminals of the single spin orbit torque element,
wherein the switching device is configured to switch the time-variant input signal with alternating polarity between the central contact terminal and the two mutually opposite contact terminals, such that, proceeding from the central contact terminal, a first signal-carrying direction directed between the central contact terminal and the first contact terminal is established in the spin orbit torque conductor, and such that a second signal-carrying direction directed between the central contact terminal and the opposite second contact terminal is established in the second spin orbit torque conductor,
wherein the first signal-carrying direction extends opposite to the second signal-carrying direction.

9. The device as claimed in claim 8, wherein the spin orbit torque conductor is arranged in parallel fashion next to the second spin orbit torque conductor, or along in a series with the second spin orbit torque conductor, and
wherein the control unit is configured to apply the time-variant input signal with temporally varying polarity to the second spin orbit torque conductor, wherein the time-variant input signal at the second spin orbit torque conductor is fed in oppositely to the time-variant input signal at the spin orbit torque conductor, such that the first and the second signal-carrying directions of the time-variant input signal in the respective-spin orbit torque conductor and the second spin orbit torque conductor, respectively, are directed oppositely to one another in each case.

10. The device as claimed in claim 9, wherein the spin orbit torque conductor and the second spin orbit torque conductor are hardwired to one another in a ring-shaped topology, such that a first section of the spin orbit torque conductor and a first section of the second spin orbit torque conductor are at a first common potential, and such that a second section of the spin orbit torque conductor and a second section of the second spin orbit torque conductor are at a second common potential,
wherein the device comprises a signal source configured to feed the spin orbit torque conductor and the second spin orbit torque conductor with a common input signal,
wherein the signal source is configured to invert the common input signal in a time-variant manner,
wherein a first terminal of the signal source is connected to the first section of the spin orbit torque conductor and the first section of the second spin orbit torque conductor, and
wherein a second terminal of the signal source is connected to the second section of the spin orbit torque conductor and the second section of the second spin orbit torque conductor such that the first signal-carrying direction in the spin orbit torque conductor is opposite to the second signal-carrying direction in the second spin orbit torque conductor.

11. The device as claimed in claim 5, wherein the first plurality of 1 to n layer stacks of the spin orbit torque conductor are arranged in terms of cardinal number from 1 to n in a first direction along the spin orbit torque conductor, and
wherein the second plurality of 1 to n layer stacks of the second spin orbit torque conductor are arranged in terms of cardinal number from 1 to n in a second direction, opposite to the first direction, along the second spin orbit torque conductor,
wherein a respective first layer stack of the first plurality of 1 to n layer stacks of the spin orbit torque conductor is electrically cross-coupled, in each case from 1 to n, to a respective second layer stack of the second plurality of 1 to n layer stacks of the second spin orbit torque conductor, and
wherein the respective first layer stack and the respective second layer stack, in each case from 1 to n, are associated with a same cardinal number.

12. The device as claimed in claim 5, wherein the control unit is configured to carry out a differential measurement of output signals of a plurality of layer stacks in order to determine the magnetic field,
wherein carrying out the differential measurement includes:
applying a first read-out current to one or more layer stacks of the first plurality of 1 to n layer stacks of the spin orbit torque conductor, the first read-out current generating a first output signal representing a conductance of the one or more layer stacks of the first plurality of 1 to n layer stacks, and
applying a second read-out current to one or more layer stacks of the second plurality of 1 to n layer stacks of the second spin orbit torque conductor, the second read-out current generating a second output signal representing a conductance of the one or more layer stacks of the second plurality of 1 to n layer stacks,
wherein the one or more layer stacks of the first plurality of 1 to n layer stacks are cross-coupled to the one or more layer stacks of the second plurality of 1 to n layer stacks, and
wherein the control unit is configured to combine at least the first output signal and the second output signal with one another to determine a total output signal and, based on the total output signal, to determine the magnetic field.

13. The device as claimed in claim 12, wherein the first read-out current is fed in at a first subset of layer stacks of the first plurality of 1 to n layer stacks of the spin orbit torque conductor, and
wherein the first read-out current is extracted at a second subset of layer stacks of the first plurality of 1 to n layer stacks of the spin orbit torque conductor.

14. The device as claimed in claim 13, wherein, in a first operating phase, the first read-out current is fed in at the first subset of the first plurality of 1 to n layer stacks of the spin orbit torque conductor and is coupled out at the second subset of layer stacks of the first plurality of 1 to n layer stacks of the spin orbit torque conductor, and
wherein, in a second operating phase, the first read-out current is fed in at the second subset of layer stacks of the first plurality of 1 to n layer stacks of the spin orbit torque conductor and is coupled out at the first subset of layer stacks of the first plurality of 1 to n layer stacks of the spin orbit torque conductor.

15. The device as claimed in claim 1, wherein the time varying signal is a time-variant input signal with temporally varying polarity.

16. A method for detecting an external magnetic field with a device, the method comprising:
feeding a time-variant input signal into a spin orbit torque conductor,
wherein the spin orbit torque conductor is arranged on a first side of a layer stack,
wherein the layer stack comprises a ferromagnetic layer, at least one magnetic reference layer and a layer arranged between the ferromagnetic layer and the at least one magnetic reference layer, wherein the layer has a magnetic tunnel junction,
wherein the at least one magnetic reference layer has a fixed first magnetization direction,
wherein the ferromagnetic layer has a variable second magnetization direction,
wherein the variable second magnetization direction is variable relative to the fixed first magnetization direction based on a spin orbit torque effect, and
wherein the first side is adjacent to the ferromagnetic layer;
feeding a read-out current to flow between an electrical conductor and the spin orbit torque conductor, such that the read-out current passes through the layer stack in order to generate a voltage drop across the magnetic tunnel junction,
wherein the time-variant input signal is in time intervals simultaneous with the read-out current; and
detecting an external magnetic field acting on the device based on the time-variant input signal and the read-out current.
